(19) United States
(12) Patent Application Publication
(10) Pub. No.: US 2025/0307075 A1
(43) Pub. Date: Oct. 2, 2025

(54) SEMICONDUCTOR MEMORY DEVICE INCLUDING ERROR CORRECTION CIRCUIT

(71) Applicant: Samsung Electronics Co., Ltd., Suwon-si (KR)

(72) Inventors: Kyu-Chang KANG, Suwon-si (KR); Younghun SEO, Suwon-si (KR)

(73) Assignee: Samsung Electronics Co., Ltd., Suwon-si (KR)

(21) Appl. No.: 19/056,142

(22) Filed: Feb. 18, 2025

(30) Foreign Application Priority Data
Apr. 1, 2024 (KR) 10-2024-0044272

(51) Int. Cl. G06F 11/10

(52) U.S. Cl. CPC G06F 11/1096

(57) ABSTRACT

A semiconductor memory device includes a memory cell array in a first semiconductor structure and including a memory area configured to store main data and a parity area configured to store parity data corresponding to the main data, a first ECC engine in a second semiconductor structure bonded to the first semiconductor structure through metal pads, configured to generate parity data corresponding to write main data, and to generate check data corresponding to read main data, a second ECC engine in the second semiconductor structure and configured to generate an error correction signal based on the parity and check data, and a data corrector in the second semiconductor structure and configured to correct read main data from the memory area based on the error correction signal. The first ECC engine and the data corrector vertically overlap the memory area, and the second ECC engine vertically overlaps the parity area.

### CROSS-REFERENCE TO RELATED APPLICATIONS

This application claims priority under 35 U.S.C. § 119 to Korean Patent Application No. 10-2024-0044272 filed on Apr. 1, 2024, in the Korean Intellectual Property Office, the disclosures of which are incorporated by reference herein in their entireties.

### BACKGROUND

Various example embodiments described herein relate to a semiconductor device, and more particularly, relate to a semiconductor memory device including an error correction circuit.

A semiconductor memory is classified as a volatile memory, which loses data stored therein when a power is turned off, or a non-volatile memory device, which retains data stored therein even when a power is turned off, such as a flash memory. Various volatile memory devices may include a static random access memory (SRAM) and/or a dynamic random access memory (DRAM). Various non-volatile memory devices may include one or more of a phase-change RAM (PRAM), a magnetic RAM (MRAM), a resistive RAM (RRAM), or a ferroelectric RAM (FRAM).

The DRAM device includes memory cells connected to a word line (a row line) and a bit line (a column line). Through bit lines, the DRAM device stores data in memory cells or reads data stored in memory cells. Various factors may cause an error in data stored in the DRAM device. A separate circuit and an additional operation are required to correct an error occurring in data stored in the DRAM device.

### SUMMARY

Various example embodiments provide a semiconductor memory device having an improved degree of integration and capable of improving an error correction speed.

According to some example embodiments, a semiconductor memory device includes a memory cell array in a first semiconductor structure and including a memory area configured to store main data and a parity area configured to store parity data corresponding to the main data, a first error correction circuit (ECC) engine in a second semiconductor structure bonded to the first semiconductor structure through a plurality of metal pads, configured to generate parity data corresponding to write main data, and to generate check data corresponding to read main data, a second ECC engine in the second semiconductor structure and configured to generate an error correction signal based on the parity data and the check data, and a data corrector in the second semiconductor structure and configured to correct read main data read from the memory area based on the error correction signal. The first ECC engine and the data corrector at least partially vertically overlap the memory area, and the second ECC engine at least partially vertically overlaps the parity area.

Alternatively or additionally according to various example embodiments, a semiconductor memory device includes a first semiconductor structure that includes one or more first sub memory cell arrays configured to store main data and a second sub memory cell array configured to store parity data corresponding to the main data, and a second semiconductor structure bonded to the first semiconductor structure through a plurality of bonding pads. The second semiconductor structure includes one or more first ECC engines configured to generate the parity data based on write main data and to generate check data based on read main data, a second ECC engine configured to generate a correction signal based on the parity data and the check data, and one or more data correctors configured to correct read main data received from the first sub memory cell array based on the data correction signal. Each of the first ECC engines and each of the data correctors at least partially vertically overlap each of the first sub memory cell arrays, and the second ECC engine at least partially vertically overlaps the second sub memory cell array.

Alternatively or additionally according to some example embodiments, a semiconductor memory device includes a first semiconductor structure that includes a memory area configured to store main data and a parity area configured to store parity data corresponding to the main data, a second semiconductor structure that includes a first bit line sense amplifier block and a second bit line sense amplifier block connected to bit lines of the memory area, a first local sense amplifier block connected to the first bit line sense amplifier block, a second local sense amplifier block connected to the second bit line sense amplifier block, a third bit line sense amplifier block and a fourth bit line sense amplifier block connected to bit lines of the parity area, and a first sub word line driver block and a second sub word line driver block configured to drive word lines of at least one of the memory area or the parity area, and a third semiconductor structure that includes an error correction circuit configured to generate the parity data based on write main data and to generate an error correction signal based on the parity data. Each of the first local sense amplifier block and the second local sense amplifier block includes data correctors configured to correct read main data based on the error correction signal.

### BRIEF DESCRIPTION OF THE DRAWINGS

The above and other objects and features of inventive concepts will become apparent by describing in detail embodiments thereof with reference to the accompanying drawings.

FIG. 1 is a block blocks indicating a semiconductor memory device.

FIG. 2 is a block diagram illustrating a semiconductor memory device according to various example embodiments.

FIG. 3 is a diagram illustrating a semiconductor memory device of FIG. 2.

FIG. 4 is a diagram for describing a write operation of a semiconductor memory device of FIG. 3.

FIG. 5 is a diagram for describing a read operation of a semiconductor memory device of FIG. 3.

FIG. 6 is a diagram illustrating a first ECC engine of a semiconductor memory device of FIG. 3.

FIG. 7 is a diagram illustrating a second ECC engine of a semiconductor memory device of FIG. 3.

FIG. 8 is a diagram illustrating a local sense amplifier of a semiconductor memory device of FIG. 3.

FIG. 9 is a perspective view illustrating a semiconductor memory device according to various example embodiments.

FIG. 10 is a view illustrating vertical cross sections taken along line A-A′ and line B-B′ of FIG. 9.

FIG. 11 is a view illustrating vertical cross sections taken along line C-C′ and line D-D′ of FIG. 9.

FIG. 12 is a view illustrating vertical cross sections taken along line E-E′ and line F-F′ of FIG. 9.

FIG. 13A is a plan view of an arrangement of a first semiconductor structure according to various example embodiments.

FIG. 13B is a plan view of an arrangement of a second semiconductor structure according to various example embodiments.

FIG. 14 is a perspective view illustrating a semiconductor memory device according to another embodiment of the present disclosure.

FIG. 15 is a diagram illustrating an integrated circuit device.

FIG. 16 is a diagram illustrating a pad array of an integrated circuit device of FIG. 15.

FIG. 17 is a diagram illustrating a vertical cross section of an integrated circuit device taken along line A-A′ of FIG. 16.

### DETAILED DESCRIPTION

Below, various example embodiments will be described in detail and clearly to such an extent that one of ordinary skill in the art may easily carries out inventive concepts. Details such as details components and structures are provided only for the overall understanding of example embodiments. Therefore, modifications of the embodiments disclosed herein may be made by one of ordinary skill in the art without departing from the spirit and scope of the invention. Moreover, descriptions of well-known functions and structures may be omitted for clarity and conciseness. In the following drawings or in the detailed description, components may be connected to any other components except for components illustrated in a drawing and/or described in the detailed description as not being connected. Terms used in the specification are terms defined in consideration of functions of inventive concepts and are not limited thereto. The definition of the terms should be determined based on the content throughout the specification.

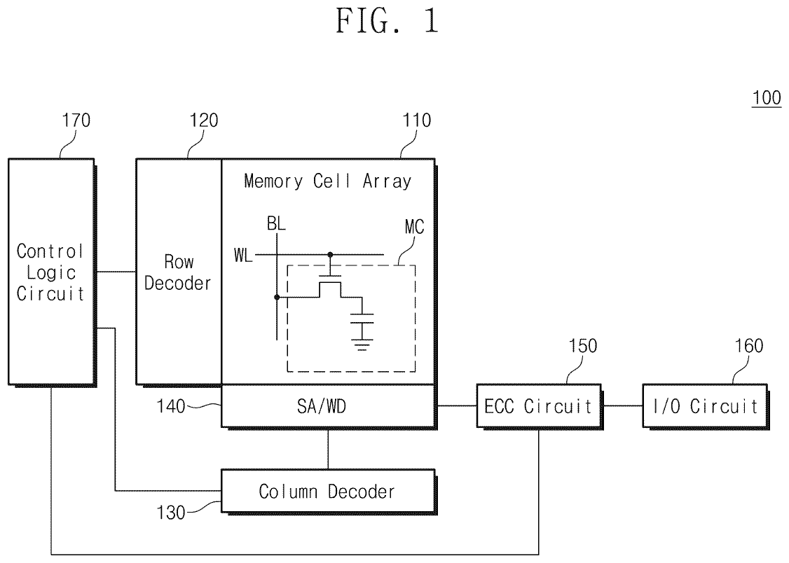

FIG. 1 is a block blocks indicating a semiconductor memory device. Referring to FIG. 1, a semiconductor memory device 100 may include a memory cell array 110, a row decoder 120, a column decoder 130, a sense amplifier and write driver 140, an error correction circuit 150, an input/output circuit 160, and a control logic circuit 170.

The semiconductor memory device 100 may include at least one of various memory devices such as a static random access memory (SRAM), a synchronous dynamic RAM (SDRAM), a magnetic RAM (MRAM), a ferroelectric RAM (FRAM), a resistive RAM (ReRAM), a phase-change RAM (PRAM), and a flash memory. Although a DRAM is illustrated, example embodiments are not limited thereto.

The memory cell array 110 may include a plurality of word lines WL, a plurality of bit lines BL, and memory cells MC connected to the word lines WL and the bit lines BL. A number of the plurality of bit lines BL may be the same as, less than, or greater than a number of the plurality of word lines WL. Each of the memory cells MC may include a selection transistor and a memory unit such as storage capacitor and/or storage memristor. The selection transistor may be connected between the storage capacitor and the bit line BL and may operate in response to a voltage of the word line WL. The storage capacitor may be connected to the selection transistor and may store data depending on an operation of the selection transistor and a voltage level of the bit line BL. The memory cell array 110 may include a plurality of sub memory cell arrays. The memory cell array 110 may further include a redundancy area (not illustrated) that may be used to correct certain defects, e.g., certain defects that occur during the fabrication of the semiconductor device; however, example embodiments are not limited thereto.

The row decoder 120 may be connected to the memory cell array 110 through the plurality of word lines WL. The row decoder 120 may decode a row address provided from the outside (e.g., from a memory controller) and may control voltages of the plurality of word lines WL based on a result of the decoding.

The column decoder 130 may be connected to the memory cell array 110 through the plurality of bit lines BL. The column decoder 130 may decode a column address provided from the outside and may control the plurality of bit lines BL based on a result of the decoding.

In a write operation, the sense amplifier and write driver 140 may write data in the memory cells MC through the plurality of bit lines BL. In a read operation, the sense amplifier and write driver 140 may read data stored in the memory cell array 110 through the plurality of bit lines BL. In some cases, there may be a refresh operation wherein some cells are read and rewritten to the memory cell array 110; however, example embodiments are not limited thereto.

In the write operation, the error correction circuit 150 may generate parity data based on write main data provided through the input/output circuit 160 and may store a codeword including the main data and the parity data in the memory cell array 110. In the read operation, the error correction circuit 150 may receive the codeword. The error correction circuit 150 may correct an error of the main data based on the parity data included in the codeword. The error correction circuit 150 may provide the corrected main data to the input/output circuit 160.

The input/output circuit 160 may receive data from the outside of the semiconductor memory device 100 and/or may provide data to the outside of the semiconductor memory device 100. For example, in the write operation, the input/output circuit 160 may be provided with the write main data from the outside of the semiconductor memory device 100. In the read operation, the input/output circuit 160 may provide read main data corresponding to an address provided from the outside of the semiconductor memory device 100.

The control logic circuit 170 may control some or all the operations of the semiconductor memory device 100. For example, the control logic circuit 170 may generate a control signal such that the semiconductor memory device 100 performs the write operation or the read operation. The control logic circuit 170 may decode a command and an address received from the outside of the semiconductor memory device 100 and may generate a control signal for controlling each component of the semiconductor memory device 100.

The semiconductor memory device 100 may detect or correct an error of the main data that is stored in the memory cell array 110 within an error detection or correction range. Accordingly, the reliability of the semiconductor memory device 100 may increase. However, because the error correction circuit 150 is an additional circuit component for generating and storing the parity data, the area of the semiconductor memory device 100 may increase. Also, because an additional operation for correcting an error of the main data is required, an operating speed may decrease.

The semiconductor memory device 100 according to various example embodiments may have a cell on peri (CoP) structure. The semiconductor memory device 100 of the CoP structure may include a first semiconductor structure including the memory cell array 110 and a second semiconductor structure including a peripheral circuit. The second semiconductor structure may include the error correction circuit 150. The first semiconductor structure and the second semiconductor structure may be vertically disposed. Below, for convenience of description, it is assumed that the second semiconductor structure is disposed under (e.g., directly under) the first semiconductor structure. The error correction circuit 150 may be disposed under the memory cell array 110 so as to vertically overlap or at least partially vertically overlap each other.

The first semiconductor structure and the second semiconductor structure may include a plurality of metal pads, and may include the same or a different number of metal pads. The plurality of metal pads may be disposed in various shapes including a matrix array shape. The metal pads of the first semiconductor structure and the metal pads of the second semiconductor structure may have the same arrangement. The metal pads may include one or more of copper (Cu), aluminum (Al), nickel (Ni), cobalt (Co), tungsten (W), titanium (Ti), tin (Sn), or an alloy thereof; the metal included in the metal pads of the first semiconductor structure may be the same as, or different from, the metal included in the metal pads of the second semiconductor structure. The first semiconductor structure and the second semiconductor structure may be bonded to each other, e.g., through the metal pads. The bonded metal pads provide a transfer of a signal or a power between the first semiconductor structure and the second semiconductor structure. As used herein, when two or more structures are described as being bonded to one another, this indicates that the two structures include certain structural elements, such as metal pads and/or solder balls, etc., that connect and bond the structures to one another.

In the semiconductor memory device 100 according to various example embodiments, the memory cell array 110 may be disposed in the first semiconductor structure, and the error correction circuit 150 may be disposed in the second semiconductor structure. Because the semiconductor memory device 100 has the CoP structure, the storage capacity of the semiconductor memory device 100 may increase, and a degree of integration of the semiconductor memory device 100 may become higher. Alternatively or additionally, the space utilization of the semiconductor memory device 100 may be improved. The error correction circuit 150 may be disposed under the memory cell array 110. In this case, a physical distance between the memory cell array 110 and the error correction circuit 150 may be decreased. Accordingly, an electrical characteristic associated with the signal transfer between the memory cell array 110 and the error correction circuit 150 may be improved.

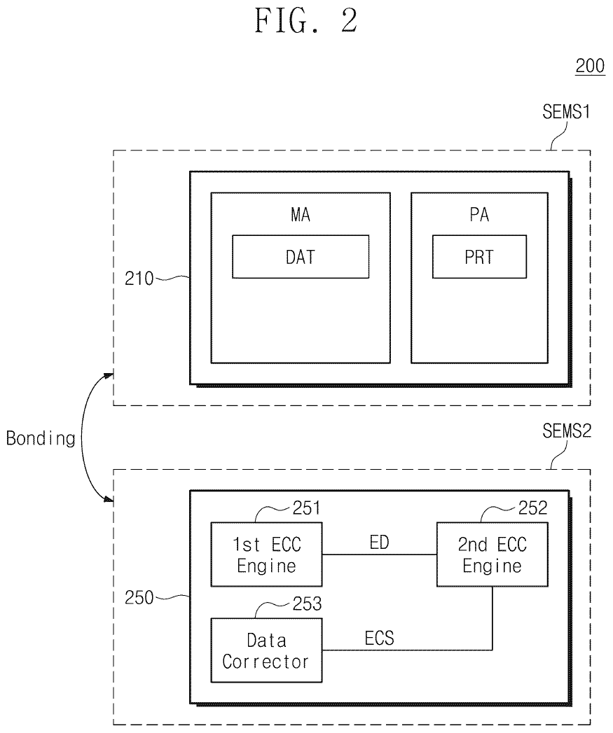

FIG. 2 is a block diagram illustrating a semiconductor memory device according to various example embodiments. Referring to FIG. 2, a semiconductor memory device 200 may include a first semiconductor structure SEMS1 and a second semiconductor structure SEMS2.

Each of the first semiconductor structure SEMS1 and the second semiconductor structure SEMS2 may include a plurality of metal pads (not illustrated). The first semiconductor structure SEMS1 and the second semiconductor structure SEMS2 may be bonded through the plurality of metal pads disposed on the surface of each structure. The bonding of the plurality of metal pads provides a signal path between the first semiconductor structure SEMS1 and the second semiconductor structure SEMS2. The bonding of the plurality of metal pads may be based on a solder-bonding technique and/or an adhesive metal bonding technique; example embodiments are not limited thereto.

The first semiconductor structure SEMS1 may include a memory cell array 210. The second semiconductor structure SEMS2 may include an error correction circuit 250.

The memory cell array 210 may include a memory area MA and a parity area PA. The memory area MA may include one or more sub memory cell arrays. Main data DAT may be stored in memory cells included in the memory area MA. The parity area PA may include one or more sub memory cell array. Parity data PRT corresponding to the main data DAT may be stored in memory cells included in the parity area PA. The main data DAT and the parity data PRT corresponding to the main data DAT may constitute (or correspond to) a codeword.

The main data DAT may be or may include data provided from the outside of the semiconductor memory device 200. The main data DAT may be classified as write main data requested to be written in the memory area MA through the write operation or read main data read from the memory area MA through the read operation. The semiconductor memory device 200 may store the main data DAT provided from the outside in the memory area MA of the memory cell array 210. An error may occur in the main data DAT due to various causes such as but not limited to a soft error and/or a voltage error and/or a signal error. For example, the write main data and the read main data may be different due to the error.

The parity data PRT are generated by error correction code “ECC” encoding of the error correction circuit 250. When the read operation is performed to read the main data DAT from the memory area MA, the error correction circuit 250 may determine whether an error occurs based on the parity data PRT received from the parity area PA or may determine a location where the error occurs based on the parity data PRT. The error correction circuit 250 may detect or both detect and correct an error occurring in the read main data based on the parity data PRT. The size of the parity data PRT may be determined in advance, depending on the size of the main data DAT, an error detection or correction capability of the error correction circuit 250, an error correction method, a probability of an error occurring, etc.

The error correction circuit 250 may include a first ECC engine 251, a second ECC engine 252, and a data corrector 253.

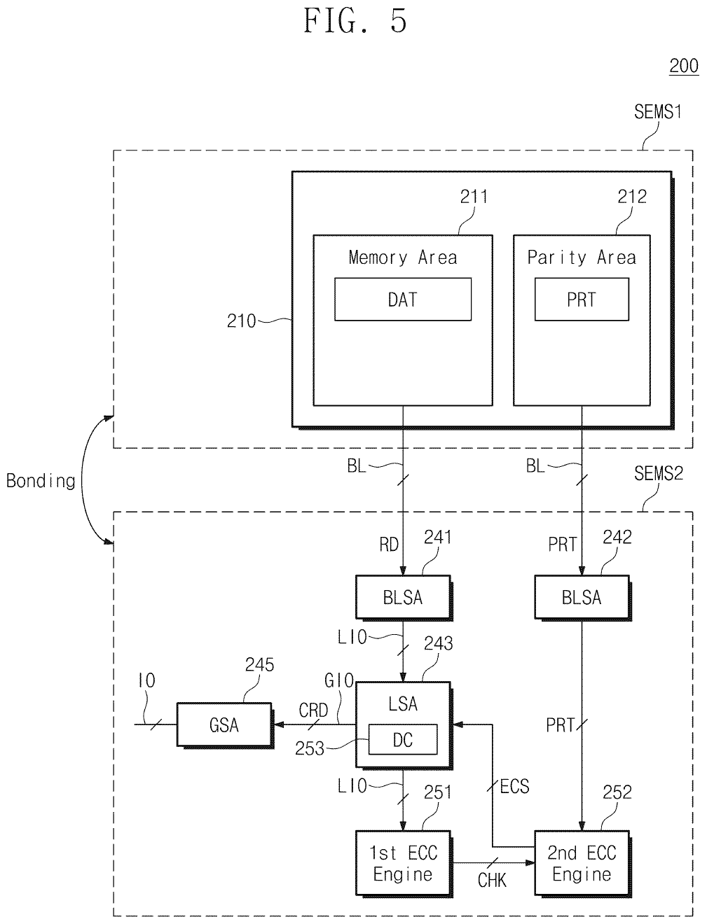

The first ECC engine 251 may perform ECC encoding for input data. The first ECC engine 251 may generate ECC data ED as a result of performing ECC encoding for the input data. The ECC data ED may correspond to one of the parity data PRT generated based on the write main data or check data (e.g., CHK of FIG. 5) based on the read main data. For example, in the write operation of the semiconductor memory device 200, the first ECC engine 251 may generate the parity data PRT corresponding to the write main data. In the read operation of the semiconductor memory device 200, the first ECC engine 251 may generate the check data corresponding to the read main data. The check data refer to data which are used to determine whether an error occurs in the main data or to determine an error occurrence location. The check data generated by the first ECC engine 251 are transferred to the second ECC engine 252.

The second ECC engine 252 may determine whether an error occurs in the main data DAT or a location where the error occurs (e.g., if an error occurs, the second ECC engine 252 may, in some cases, determine a location where the error occurs). In the read operation of the semiconductor memory device 200, the second ECC engine 252 may receive the parity data PRT from the parity area PA and may receive the check data generated based on the read main data from the first ECC engine 251. The second ECC engine 252 may generate an error correction signal ECS based on the parity data PRT and the check data. For example, the error correction signal ECS may include a plurality of signals each having one of a first value (e.g., a logic low level) or a second value (e.g., a logic high level). The plurality of signals included in the error correction signal ECS respectively correspond to a plurality of bits included in the main data DAT. In the error correction signal ECS, a signal of the first value may indicate that an error does not occur at a bit of the main data DAT, the location of which corresponds to the signal of the first value. In the error correction signal ECS, a signal of the second value may indicate that an error occurs at a bit of the main data DAT, the location of which corresponds to the signal of the second value. Through the above manner, for each of the plurality of bits included in the main data DAT, the error correction signal ECS may indicate whether an error occurs, or an error occurrence location. For example, if an error occurs, the error correction signal ECS may indicate that an error occurred, or may indicate that an error occurred and also a location the error occurrence.

The data corrector 253 may correct an error of the read main data, based on the read main data received from the memory area MA and the error correction signal ECS received from the second ECC engine 252. For example, the data corrector 253 may invert or negate at least one bit included in the main data DAT based on the error correction signal ECS. The data corrector 253 may invert or negate a bit of the main data DAT, which corresponds to a signal having the second value from among the plurality of signals included in the error correction signal ECS. The data corrector 253 may generate the corrected read main data by inverting or negating at least one of the plurality of bits included in the read main data. The corrected read main data may be provided to the outside of the semiconductor memory device 200.

The first ECC engine 251, the second ECC engine 252, and the data corrector 253 are disposed in the second semiconductor structure SEMS2. In detail, the first ECC engine 251 and the data corrector 253 may be disposed under the memory area MA, and the second ECC engine 252 may be disposed under the parity area PA. In this case, the first ECC engine 251 and the data corrector 253 may vertically overlap or at least partially vertically overlap the memory area MA. The second ECC engine 252 may vertically overlap or at least partially vertically overlap the parity area PA.

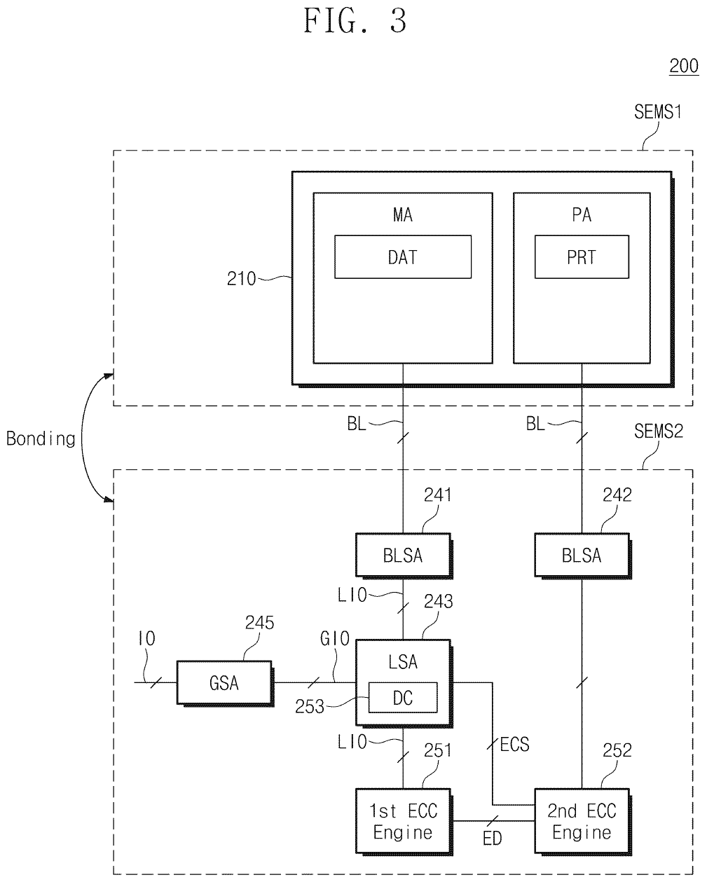

FIG. 3 is a diagram illustrating a semiconductor memory device of FIG. 2. Referring to FIG. 3, the second semiconductor structure SEMS2 may include a bit line sense amplifier 241, a local sense amplifier 243, and a global sense amplifier 245.

The bit line sense amplifier 241 is connected to memory cells of the memory area MA through the bit lines BL. The bit line sense amplifier 241 may sense and amplify the main data DAT stored in the memory area MA so as to be output to local input/output lines LIO. The main data DAT on the local input/output lines LIO are transferred to the local sense amplifier 243 and the first ECC engine 251. The local sense amplifier 243 may sense and amplify data on the local input/output lines LIO so as to be output to global input/output lines GIO. The global sense amplifier 245 may sense and amplify data on the global input/output lines GIO so as to be output to data input/output lines IO. Each of the bit lines BL, the local input/output lines LIO, and the global input/output lines GIO may be implemented with a complementary line pair (or a split-rail pair).

The first ECC engine 251 may be connected to the local input/output lines LIO. The first ECC engine 251 may perform ECC encoding for the main data DAT received through the local input/output lines LIO. The ECC data ED generated through the ECC encoding for the main data DAT are transferred to the second ECC engine 252. For example, in the write operation, the write main data may be input to the first ECC engine 251 through the local input/output lines LIO. The first ECC engine 251 may generate the parity data PRT based on the write main data. The parity data PRT may be transferred to the second ECC engine 252 and may be stored in the parity area PA. In the read operation, the read main data may be input to the first ECC engine 251 through the local input/output lines LIO. The first ECC engine 251 may generate the check data based on the read main data. The check data are transferred to the second ECC engine 252.

The second semiconductor structure SEMS2 may further include a bit line sense amplifier 242. The bit line sense amplifier 242 is connected to memory cells of the parity area PA through the bit lines BL included in the parity area PA. The bit line sense amplifier 242 may sense and amplify the parity data PRT stored in the parity area PA so as to be output to the second ECC engine 252.

In the read operation, the second ECC engine 252 may receive the parity data PRT from the parity area PA and may receive the check data from the first ECC engine 251. The second ECC engine 252 may generate the error correction signal ECS based on the parity data PRT and the check data. The error correction signal ECS may be transferred to the local sense amplifier 243.

The local sense amplifier 243 may include the data corrector 253. In the read operation, the data corrector 253 may correct the read main data received from the bit line sense amplifier 241, based on the error correction signal ECS received from the second ECC engine 252. The corrected read main data are output to the global input/output lines GIO. For example, the data corrector 253 may invert or negate one or more of the plurality of bits included in the read main data based on one or more signal with the second value among a plurality of signals included in the error correction signal ECS. The corrected read main data output from the data corrector 253 are transferred to the global input/output lines GIO through the local sense amplifier 243.

The bit line sense amplifier 241, the local sense amplifier 243, and the first ECC engine 251 may be disposed under the memory area MA. In this case, the first ECC engine 251 may vertically overlap or at least partially vertically overlap the memory area MA. As the first ECC engine 251 is disposed relatively close to the memory area MA, an electrical characteristic of a path through which the main data DAT are transferred may be improved. This indicate mean that the performance of operation of the first ECC engine 251 is improved. Alternatively or additionally, the bit line sense amplifier 242 and the second ECC engine 252 may be disposed under the parity area PA. The second ECC engine 252 may vertically overlap or at least partially vertically overlap the parity area PA. As the second ECC engine 252 is disposed relatively close to the parity area PA, an electrical characteristic of a path through which the parity data PRT are transferred may be improved. As the performance of operation of the first ECC engine 251 and the second ECC engine 252 are improved, the operating speed of the semiconductor memory device 200 may become higher, and/or power consumption may be reduced.

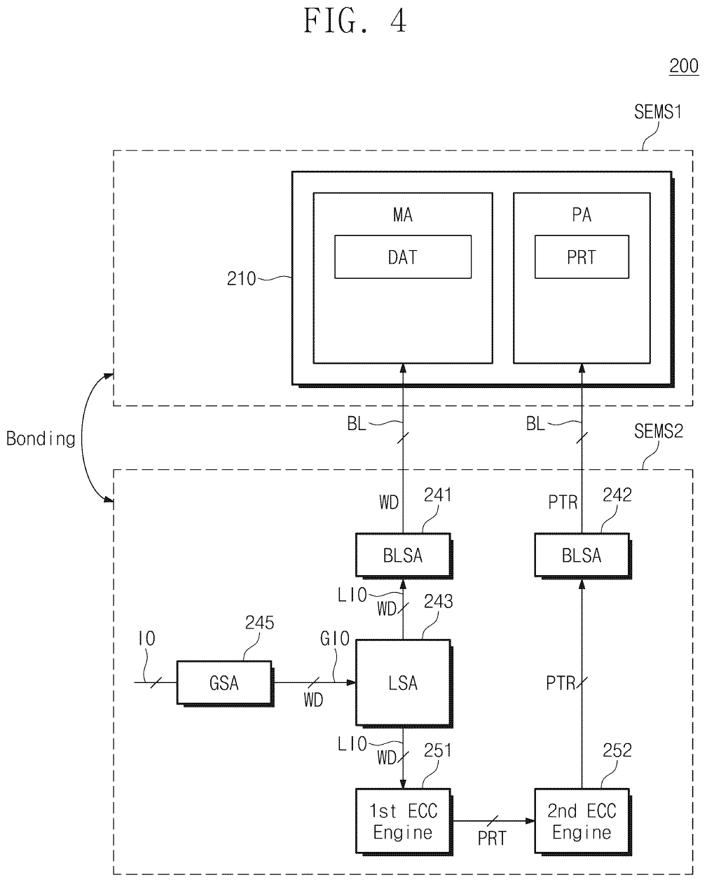

FIG. 4 is a diagram for describing a write operation of a semiconductor memory device of FIG. 3. Referring to FIG. 4, in the write operation, the main data DAT and the parity data PRT may be written in the memory cell array 210.

In the write operation for the main data DAT, the semiconductor memory device 200 ma receive the write main data WD from the outside through the data input/output lines IO. A write driver (not illustrated) may write the main data DAT in memory cells of the memory area MA. The write main data WD are transferred to the memory area MA through the global input/output lines GIO, the local input/output lines LIO, and the bit lines BL. Accordingly, the main data DAT may be written in the memory area MA.

The write main data WD are input to the first ECC engine 251 through the local input/output lines LIO. The first ECC engine 251 may perform ECC encoding for the write main data WD. In this case, the first ECC engine 251 may generate the parity data PRT based on the write main data WD. The parity data PRT may be transferred to the parity area PA through the second ECC engine 252 and the bit lines BL. The parity data PRT corresponding to the main data DAT are written in the parity area PA. In some example embodiments, the parity data PRT may be directly transferred to the bit lines BL without passing through the second ECC engine 252.

FIG. 5 is a diagram for describing a read operation of a semiconductor memory device of FIG. 3. Referring to FIG. 5, in the read operation, the main data DAT read from the memory cell array 210 may be corrected.

In the read operation for the main data DAT, the bit line sense amplifier 241 may sense and amplify a signal associated with the main data DAT. Read main data RD are transferred to the local input/output lines LIO.

The first ECC engine 251 may perform ECC encoding for the read main data RD received through the local input/output lines LIO. In this case, the first ECC engine 251 may generate the check data CHK based on the read main data RD.

In the read operation for the main data DAT, the bit line sense amplifier 242 may sense and amplify a signal associated with the parity data PRT. The parity data PRT are transferred to the second ECC engine 252.

In the read operation for the main data DAT, the second ECC engine 252 may receive the check data CHK from the first ECC engine 251 and may receive the parity data PRT from the parity area PA. The second ECC engine 252 may generate the error correction signal ECS based on the check data CHK and the parity data PRT. The error correction signal ECS may be transferred to the local sense amplifier 243.

The local sense amplifier 243 may receive the read main data RD through the local input/output lines LIO. In this case, the data corrector 253 included in the local sense amplifier 243 may correct the read main data RD based on the error correction signal ECS. The local sense amplifier 243 transfers corrected read main data CRD to the global sense amplifier 245 through the global input/output lines GIO. The global sense amplifier 245 may transfer the corrected read main data CRD to the data input/output lines IO. The semiconductor memory device 200 may provide the corrected read main data CRD to the outside.

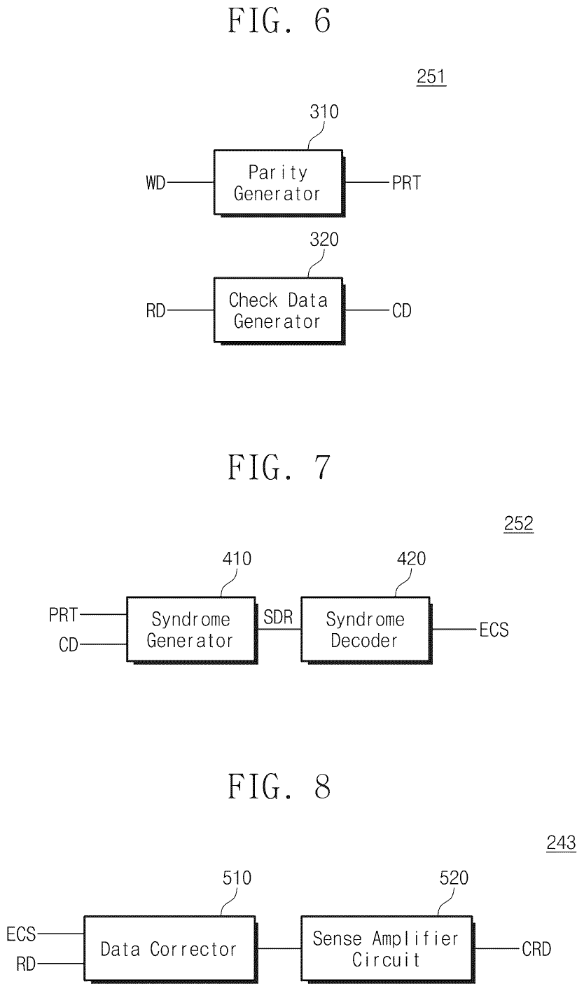

FIG. 6 is a diagram illustrating a first ECC engine of a semiconductor memory device of FIG. 3. Referring to FIG. 6, the first ECC engine 251 may include a parity generator 310.

In the write operation, the write main data WD may be input to the parity generator 310. The parity generator 310 may generate the parity data PRT based on the write main data WD. The parity generator 310 may generate the parity data PRT by performing exclusive OR (XOR) operations on combinations of bits constituting the write main data WD. The first ECC engine 251 may include an arithmetic and logical unit (ALU) for the XOR operation; example embodiments are not limited thereto. The parity generator 310 may use ALUs included in the first ECC engine 251 to generate the parity data PRT.

The first ECC engine 251 may further include a check data generator 320. In the read operation, the check data generator 320 may receive the read main data RD. The check data generator 320 may generate the check data CHK by performing XOR operations on combinations of bits constituting the read main data RD. The check data generator 320 may perform the XOR operation by using combinations which are the same as the combinations used when the parity data PRT are generated. The check data generator 320 may use the ALUs used to generate the parity data PRT.

When the write main data WD are the same as the read main data RD, the parity data PRT generated in the write operation may be the same as the check data CHK generated in the read operation. Meanwhile, when the write main data WD are different from the read main data RD, there may be determined that an error occurs in the main data DAT.

FIG. 7 is a diagram illustrating a second ECC engine of a semiconductor memory device of FIG. 3. Referring to FIG. 7, the second ECC engine 252 may include a syndrome generator 410 and a syndrome decoder 420.

In the read operation, the syndrome generator 410 may receive the parity data PRT and the check data CHK. The syndrome generator 410 may generate a syndrome SDR based on the parity data PRT and the check data CHK. The syndrome SDR may include information about a location of an error occurring in the read main data. To generate the syndrome SDR, the syndrome generator 410 may perform XOR operations on bits included in the parity data PRT and the check data CHK. For example, assuming that each of the parity data PRT and the check data CHK includes “n” bits, the syndrome generator 410 may compare the k-th bit (k being a natural number less than or equal to “n”) of the check data CHK and the k-th bit of the parity data PRT. When the k-bit bit of the check data CHK and the k-th bit of the parity data PRT coincide with each other, the k-th bit of the syndrome SDR may have the first value (e.g., a logic low level such as a “0”). When the k-bit bit of the check data CHK and the k-th bit of the parity data PRT are different from each other, the k-th bit of the syndrome SDR may have the second value (e.g., a logic high level such as a “1”).

The syndrome decoder 420 may decode the syndrome SDR to generate the error correction signal ECS. The error correction signal ECS may indicate a location of an error included in the main data DAT. For example, a signal, which corresponds to an erroneous bit, from among the plurality of signals included in the error correction signal ECS may have the second value.

FIG. 8 is a diagram illustrating a local sense amplifier of a semiconductor memory device of FIG. 3. Referring to FIG. 8, the local sense amplifier 243 may include a data corrector 510 and a sense amplifier circuit 520.

In the read operation, the local sense amplifier 243 may receive the error correction signal ECS from the second ECC engine 252. The error correction signal ECS may include a plurality of signals; a signal, which corresponds to an erroneous bit, from among the plurality of signals of the error correction signal ECS may have the second value. The data corrector 510 may perform the XOR operation on each bit of the read main data RD and each signal of the error correction signal ECS. he k-th bit of the error correction signal ECS having the second value may indicate that an error occurs at the k-th bit of the read main data RD. The data corrector 510 may invert/negate the k-th bit of the read main data RD through the XOR operation. For example, the read main data RD may be corrected. The sense amplifier circuit 520 may amplify the corrected read main data CRD generated through the data corrector 510 so as to be output to the global sense amplifier 245.

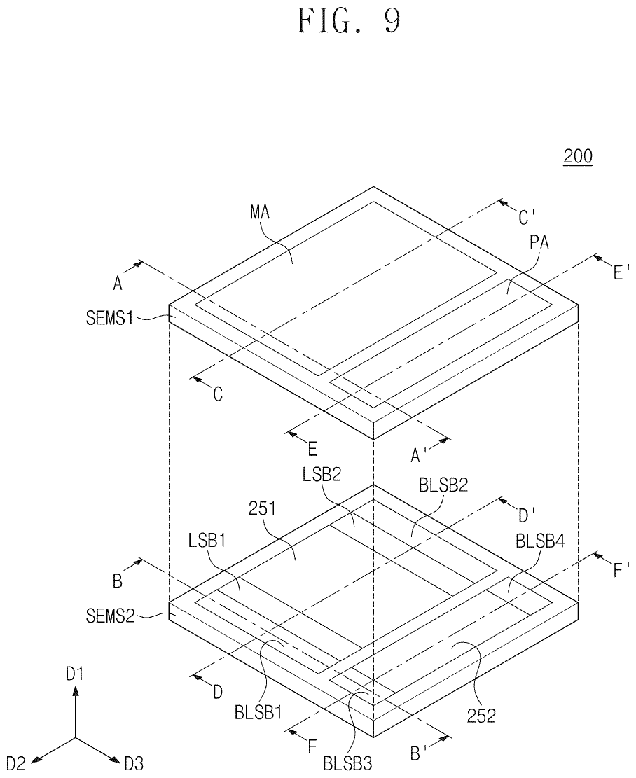

FIG. 9 is a perspective view illustrating a semiconductor memory device according to various example embodiments. Referring to FIG. 9, the semiconductor memory device 200 may include the first semiconductor structure SEMS1 and the second semiconductor structure SEMS2.

The first semiconductor structure SEMS1 and the second semiconductor structure SEMS2 may be vertically disposed through the bonding of a plurality of metal pads. Below, for convenience of description, it is assumed that the second semiconductor structure SEMS2 is disposed under the first semiconductor structure SEMS1. For example, a downward direction is a direction facing away from a first direction D1.

The first semiconductor structure SEMS1 may include the memory area MA and the parity area PA. Each of the memory area MA and the parity area PA may include at least one sub memory cell array. Each of the sub memory cell arrays may include a plurality of memory cells. Main data may be stored in the sub memory cell array included in the memory area MA. Parity data corresponding to the main data may be stored in the sub memory cell array of the parity area PA.

The second semiconductor structure SEMS2 may include a first bit line sense amplifier block BLSB1 and a second bit line sense amplifier block BLSB2. The first bit line sense amplifier block BLSB1 may be disposed under one side periphery of a lower surface (or lower portion) of the memory area MA. The second bit line sense amplifier block BLSB2 may be disposed under an opposite side periphery of the lower surface of the memory area MA. The first bit line sense amplifier block BLSB1 are electrically connected to some of a plurality of bit lines disposed in the memory area MA. The second bit line sense amplifier block BLSB2 are electrically connected to the others of the plurality of bit lines disposed in the memory area MA. Each of the first bit line sense amplifier block BLSB1 and the second bit line sense amplifier block BLSB2 may include a plurality of bit line sense amplifiers. The plurality of bit line sense amplifiers included in each of the first bit line sense amplifier block BLSB1 and the second bit line sense amplifier block BLSB2 may sense and amplify signals of the corresponding bit lines disposed in the memory area MA.

The second semiconductor structure SEMS2 may further include a first local sense amplifier block LSB1 and a second local sense amplifier block LSB2. The first local sense amplifier block LSB1 may be disposed under the memory area MA so as to be adjacent to the first bit line sense amplifier block BLSB1. The first local sense amplifier block LSB1 may sense and amplify signals output to local input/output lines through the first bit line sense amplifier block BLSB1. The second local sense amplifier block LSB2 may be disposed under the memory area MA so as to be adjacent to the second bit line sense amplifier block BLSB2. The second local sense amplifier block LSB2 may sense and amplify signals output to local input/output lines through the second bit line sense amplifier block BLSB2.

The first bit line sense amplifier block BLSB1 and the second bit line sense amplifier block BLSB2 may correspond to the bit line sense amplifier 241 of FIG. 3. The first local sense amplifier block LSB1 and the second local sense amplifier block LSB2 may correspond to the local sense amplifier 243 of FIG. 3.

The second semiconductor structure SEMS2 may further include the first ECC engine 251. The first ECC engine 251 may be disposed between the first local sense amplifier block LSB1 and the second local sense amplifier block LSB2 under the memory area MA. In the write operation, the first ECC engine 251 may perform ECC encoding for the write main data transferred through the first local sense amplifier block LSB1 or the second local sense amplifier block LSB2. As a result of the ECC encoding, the first ECC engine 251 may generate the parity data. In the read operation, the first ECC engine 251 may perform ECC encoding for the read main data transferred through the first bit line sense amplifier block BLSB1 or the second bit line sense amplifier block BLSB2. As a result of the ECC encoding, the first ECC engine 251 may generate the check data.

The first bit line sense amplifier block BLSB1, the second bit line sense amplifier block BLSB2, the first local sense amplifier block LSB1, the second local sense amplifier block LSB2, and the first ECC engine 251 may vertically overlap the memory area MA, or at least partially vertically overlap the memory area MA.

The second semiconductor structure SEMS2 may further include a third bit line sense amplifier block BLSB3 and a fourth bit line sense amplifier block BLSB4. The third bit line sense amplifier block BLSB3 may be disposed under a side periphery of a lower surface of the parity area PA. The fourth bit line sense amplifier block BLSB4 may be disposed under an opposite side periphery of the lower surface of the parity area PA. The third bit line sense amplifier block BLSB3 are electrically connected to some of a plurality of bit lines disposed in the parity area PA. The fourth bit line sense amplifier block BLSB4 are electrically connected to the others of the plurality of bit lines disposed in the parity area PA. The third bit line sense amplifier block BLSB3 and the fourth bit line sense amplifier block BLSB4 may sense and amplify signals of the bit lines disposed in the parity area PA.

The second semiconductor structure SEMS2 may further include the second ECC engine 252. The second ECC engine 252 may be disposed between the third bit line sense amplifier block BLSB3 and the fourth bit line sense amplifier block BLSB4.

The third bit line sense amplifier block BLSB3, the fourth bit line sense amplifier block BLSB4, and the second ECC engine 252 may vertically overlap or at least partially vertically overlap the parity area PA.

The third bit line sense amplifier block BLSB3 and the fourth bit line sense amplifier block BLSB4 may correspond to the bit line sense amplifier 242 of FIG. 3.

Meanwhile, in the second semiconductor structure SEMS2, the first local sense amplifier block LSB1 and the second local sense amplifier block LSB2 may be disposed under the memory area MA, but a local sense amplifier may not be disposed under the parity area PA.

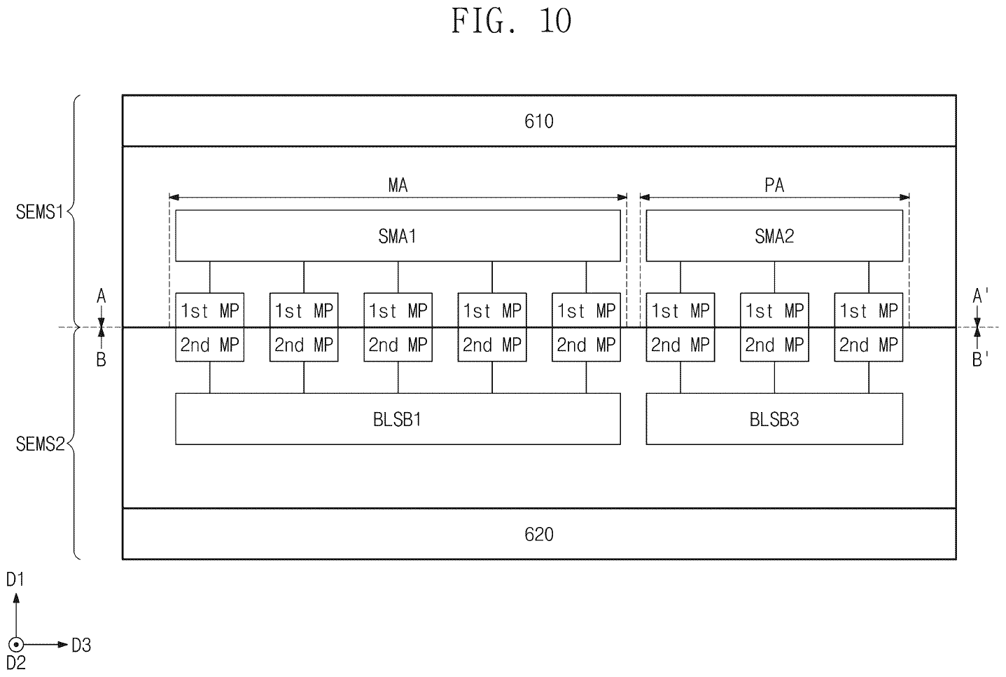

FIG. 10 is a view illustrating vertical cross sections taken along line A-A′ and line B-B′ of FIG. 9. Referring to FIG. 10, the first semiconductor structure SEMS1 may include a first substrate 610.

A memory cell array including a plurality of sub memory cell arrays may be disposed on the first substrate 610. A plurality of first metal pads 1st MP may be disposed in one surface of the first semiconductor structure SEMS1 in the shape of a matrix array. For example, a first sub memory cell array SMA1 may be disposed in the memory area MA of the first semiconductor structure SEMS1. A second sub memory cell array SMA2 may be disposed in the parity area PA of the first semiconductor structure SEMS1. Some or all of bit lines disposed in the first sub memory cell array SMA1 may be electrically connected to some of the first metal pads 1st MP through metal lines. Some or all of bit lines disposed in the second sub memory cell array SMA2 may be electrically connected to the others of the first metal pads 1st MP through metal lines.

The second semiconductor structure SEMS2 may include a second substrate 620. Bit line sense amplifiers may be disposed on the second substrate 620. A plurality of second metal pads 2nd MP may be disposed in one surface of the second semiconductor structure SEMS2 in the shape of a matrix array. For example, the first bit line sense amplifier block BLSB1 may be located in the second semiconductor structure SEMS2 under the memory area MA. The first bit line sense amplifier block BLSB1 may vertically overlap or at least partially vertically overlap the memory area MA or the first sub memory cell array SMA1. A plurality of bit line sense amplifiers included in the first bit line sense amplifier block BLSB1 may be electrically connected to some of the second metal pads 2nd MP. The third bit line sense amplifier block BLSB3 may be located in the second semiconductor structure SEMS2 under the parity area PA. The third bit line sense amplifier block BLSB3 may vertically overlap or at least partially vertically overlap the parity area PA or the second sub memory cell array SMA2. A plurality of bit line sense amplifiers included in the third bit line sense amplifier block BLSB3 may be electrically connected to the others of the second metal pads 2nd MP.

The plurality of first metal pads 1st MP disposed on the one surface of the first semiconductor structure SEMS1 and the plurality of second metal pads 2nd MP disposed on the one surface of the second semiconductor structure SEMS2 may be bonded to each other. A surface-area of a first metal pad 1st MP may be the same as, or substantially the same as, a surface area of a respective second metal pad 2nd MP bonded thereto; however, example embodiments are not limited thereto. The bonding between the first metal pads 1st MP and the second metal pads 2nd MP provides an electrical connection between the first semiconductor structure SEMS1 and the second semiconductor structure SEMS2. For example, the bonding between the first metal pads 1st MP and the second metal pads 2nd MP provides an electrical connection between the plurality of bit line sense amplifiers included in the first bit line sense amplifier block BLSB1 and some of the bit lines of the first sub memory cell array SMA1. Also, the bonding between the first metal pads 1st MP and the second metal pads 2nd MP provides an electrical connection between the plurality of bit line sense amplifiers included in the third bit line sense amplifier block BLSB3 and some of the bit lines of the second sub memory cell array SMA2.

The first bit line sense amplifier block BLSA1 may sense and amplify signals of some of the plurality of bit lines disposed in the first sub memory cell array SMA1. The third bit line sense amplifier block BLSA3 may sense and amplify signals of some of the plurality of bit lines disposed in the second sub memory cell array SMA2.

Meanwhile, referring back to FIG. 9 in more detail, in the semiconductor memory device 200, the second bit line sense amplifier block BLSB2 and the fourth bit line sense amplifier block BLSB4 may be disposed on one side facing away from the cross sections taken along line A-A′ and line B-B′. The second bit line sense amplifier block BLSB2 may vertically overlap or at least partially vertically overlap the memory area MA or the first sub memory cell array SMA1. The fourth bit line sense amplifier block BLSB4 may vertically overlap or at least partially vertically overlap the parity area PA or the second sub memory cell array SMA2. The plurality of bit line sense amplifiers included in the second bit line sense amplifier block BLSB2 are electrically and respectively connected to the others of the bit lines disposed in the first sub memory cell array SMA1 through the second metal pads 2nd MP and the first metal pads 1st MP. The second bit line sense amplifier block BLSB2 may sense and amplify signals of the others of the plurality of bit lines disposed in the first sub memory cell array SMA1. The plurality of bit line sense amplifiers included in the fourth bit line sense amplifier block BLSB4 are electrically and respectively connected to the others of the bit lines disposed in the second sub memory cell array SMA2 through the second metal pads 2nd MP and the first metal pads 1st MP. The fourth bit line sense amplifier block BLSB4 may sense and amplify signals of the others of the plurality of bit lines disposed in the second sub memory cell array SMA2.

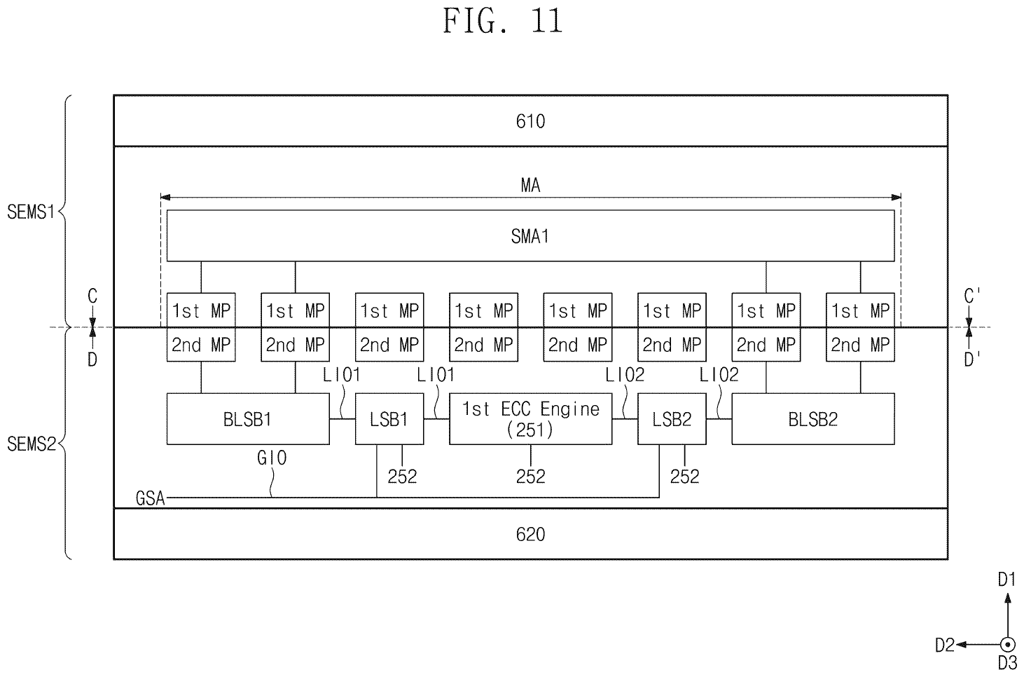

FIG. 11 is a view illustrating vertical cross sections taken along line C-C′ and line D-D′ of FIG. 9. Referring to FIG. 11, the second semiconductor structure SEMS2 may include the first bit line sense amplifier block BLSB1, the second bit line sense amplifier block BLSB2, the first local sense amplifier block LSB1, the second local sense amplifier block LSB2, and the first ECC engine 251.

Each of the first bit line sense amplifier block BLSB1, the second bit line sense amplifier block BLSB2, the first local sense amplifier block LSB1, the second local sense amplifier block LSB2, and the first ECC engine 251 may be disposed under the memory area MA. For example, the first bit line sense amplifier block BLSB1 may be located under one side periphery of the lower surface of the memory area MA. The second bit line sense amplifier block BLSB2 may be located under an opposite side periphery of the lower surface of the memory area MA. The first local sense amplifier block LSB1 may be located adjacent to the first bit line sense amplifier block BLSB1. The second local sense amplifier block LSB2 may be located adjacent to the second bit line sense amplifier block BLSB2. The first ECC engine 251 may be located between the first local sense amplifier block LSB1 and the second local sense amplifier block LSB2.

The first bit line sense amplifier block BLSB1 is connected to some of the bit lines of the first sub memory cell array SMA1 through the bonding between the first metal pads 1st MP and the second metal pads 2nd MP. The second bit line sense amplifier block BLSB2 is connected to the others of the bit lines of the first sub memory cell array SMA1 through the bonding between the first metal pads 1st MP and the second metal pads 2nd MP.

The first bit line sense amplifier block BLSB1 may sense and amplify signals of some of the plurality of bit lines disposed in the first sub memory cell array SMA1 so as to be transferred to first local input/output lines LIO1. The first local input/output lines LIO1 are connected to the first local sense amplifier block LSB1 and the first ECC engine 251. The second bit line sense amplifier block BLSB2 may sense and amplify signals of the others of the plurality of bit lines disposed in the first sub memory cell array SMA1 so as to be transferred to second local input/output lines LIO2. The second local input/output lines LIO2 are connected to the second local sense amplifier block LSB2 and the first ECC engine 251.

The first local sense amplifier block LSB1 may sense and amplify signals of the first local input/output lines LIO1 so as to be transferred to the global input/output lines GIO. The second local sense amplifier block LSB2 may sense and amplify signals of the second local input/output lines LIO2 so as to be transferred to the global input/output lines GIO.

The first bit line sense amplifier block BLSB1, the second bit line sense amplifier block BLSB2, the first local sense amplifier block LSB1, the second local sense amplifier block LSB2, and the first ECC engine 251 may vertically overlap or at least partially vertically overlap the memory area MA or the first sub memory cell array SMA1.

In the write operation, the write main data received through the global input/output lines GIO are input to the first ECC engine 251 through the first local input/output lines LIO1 or the second local input/output lines LIO2. The first ECC engine 251 may generate the parity data based on the write main data. The parity data are output to the second ECC engine 252.

In the read operation, the read main data sensed and amplified through the first bit line sense amplifier block BLSB1 or the second bit line sense amplifier block BLSB2 are input to the first ECC engine 251 through the first local input/output lines LIO1 or the second local input/output lines LIO2. The first ECC engine 251 may generate the check data corresponding to the parity data based on the read main data. The check data are output to the second ECC engine 252.

In the read operation, the second ECC engine 252 may generate the error correction signal based on the parity data and the check data. Local sense amplifiers included in the first local sense amplifier block LSB1 or the second local sense amplifier block LSB2 may receive the error correction signal from the second ECC engine 252. The local sense amplifiers included in the first local sense amplifier block LSB1 or the second local sense amplifier block LSB2 may correct the read main data based on the error correction signal. The corrected read main data are transferred to the global input/output lines GIO so as to be provided to the outside of the semiconductor memory device 200 through a global sense amplifier GSA.

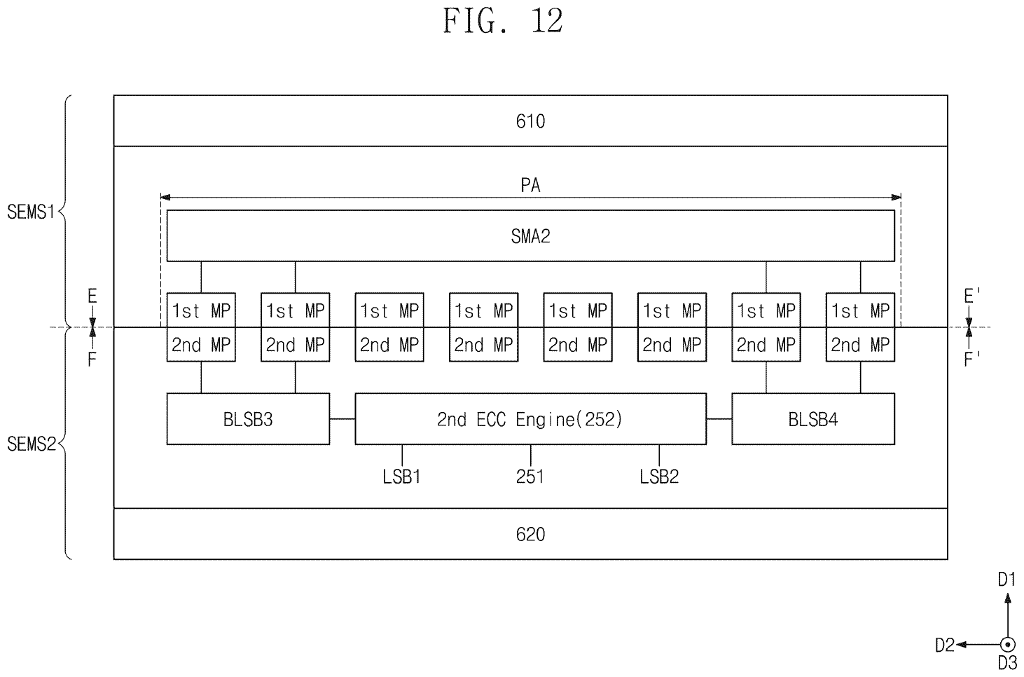

FIG. 12 is a view illustrating vertical cross sections taken along line E-E′ and line F-F′ of FIG. 9. Referring to FIG. 12, the second semiconductor structure SEMS2 may include the third bit line sense amplifier block BLB3, the fourth bit line sense amplifier block BLB4, and the second ECC engine 252.

Each of the third bit line sense amplifier block BLB3, the fourth bit line sense amplifier block BLB4, and the second ECC engine 252 may be located under the parity area PA. For example, the third bit line sense amplifier block BLSB3 may be located under one side periphery of the lower surface of the parity area PA. The fourth bit line sense amplifier block BLSB4 may be located under an opposite side periphery of the lower surface of the parity area PA. The second ECC engine 252 may be located between the third bit line sense amplifier block BLSB3 and the fourth bit line sense amplifier block BLSB4.

The third bit line sense amplifier block BLSB3 is connected to some of the bit lines of the second sub memory cell array SMA2 through the bonding between the first metal pads 1st MP and the second metal pads 2nd MP. The fourth bit line sense amplifier block BLSB4 is connected to the others of the bit lines of the second sub memory cell array SMA2 through the bonding between the first metal pads 1st MP and the second metal pads 2nd MP.

The third bit line sense amplifier block BLB3, the fourth bit line sense amplifier block BLB4, and the second ECC engine 252 may vertically overlap, or at least partly vertically overlap, the parity area PA.

The third bit line sense amplifier block BLSB3 may sense and amplify signals of the of the plurality of bit lines disposed in the second sub memory cell array SMA2 so as to be transferred to the second ECC engine 252. The fourth bit line sense amplifier block BLSB4 may sense and amplify signals of the others of the plurality of bit lines disposed in the second sub memory cell array SMA2 so as to be transferred to the second ECC engine 252.

In the write operation, the parity data generated by the first ECC engine 251 are transferred to the second sub memory cell array SMA2 through the second ECC engine 252. Meanwhile, the parity data generated by the first ECC engine 251 may be transferred to the bit lines of the second sub memory cell array SMA2 without passing through the second ECC engine 252.

In the read operation, the third bit line sense amplifier block BLSB3 or the fourth bit line sense amplifier block BLSB4 may sense and amplify signals of the bit lines disposed in the second sub memory cell array SMA2 so as to be transferred to the second ECC engine 252. The second ECC engine 252 may compare the check data received from the first ECC engine 251 and the parity data received through the third bit line sense amplifier block BLSB3 or the fourth bit line sense amplifier block BLSB4. The second ECC engine 252 may generate the error correction signal based on the comparison of the check data and the parity data. The error correction signal is transferred to the local sense amplifiers included in the first local sense amplifier block LSB1 or the second local sense amplifier block LSB2.

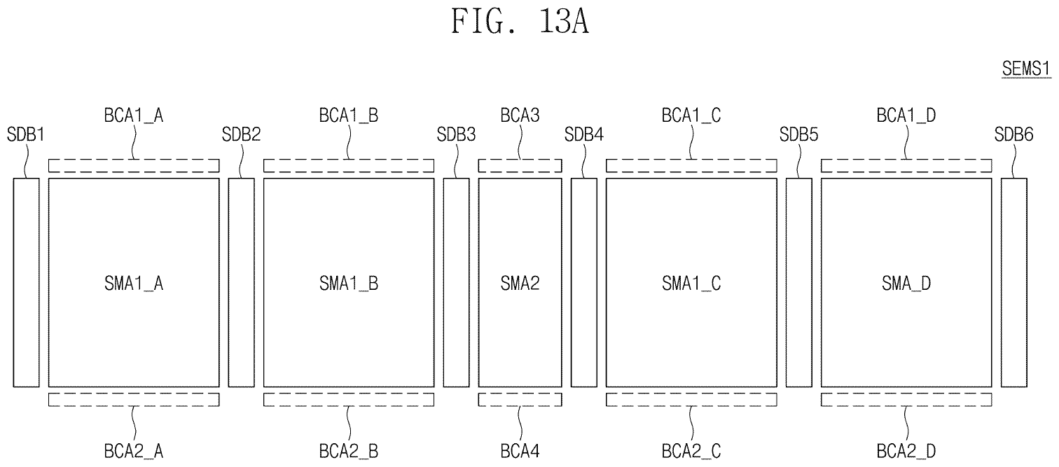

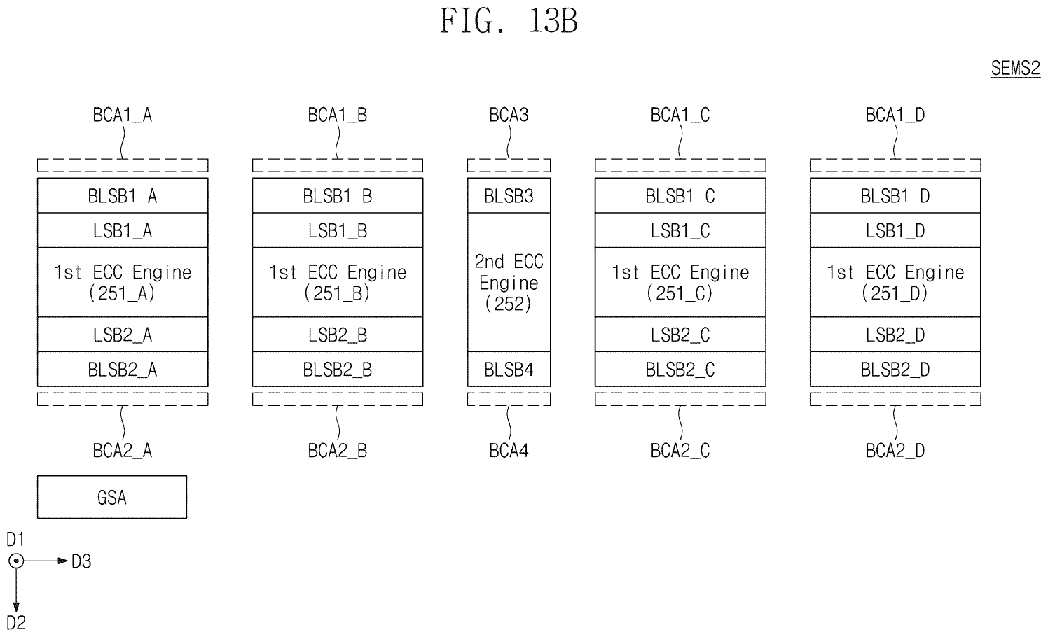

FIG. 13A is a plan view of an arrangement of a first semiconductor structure according to various example embodiments. Referring to FIG. 13A, the first semiconductor structure SEMS1 may include a plurality of first sub memory cell arrays SMA1_A, SMA1_B, . . . , SMA1_D and the second sub memory cell array SMA2.

The main data may be stored in the first sub memory cell arrays SMA1_A to SMA1_D. The parity data corresponding to the main data may be stored in the second sub memory cell array SMA2. The first semiconductor structure SEMS1 may further include a plurality of sub word line driver blocks SDB1, SDB2, . . . , SDB6. The plurality of sub word line driver blocks SDB1 to SDB6, the plurality of first sub memory cell arrays SMA1_A to SMA1_D, and the second sub memory cell array SMA2 may be disposed alternately. For example, the first sub memory cell array SMA1_A may be disposed between the sub word line driver block SDB1 and the sub word line driver block SDB2. The second sub word line driver block SDB2 may be disposed between the first sub memory cell array SMA1_A and the first sub memory cell array SMA1_B. The third sub word line driver block SDB3 may be disposed between the first sub memory cell array SMA1_B and the second sub memory cell array SMA2. The second sub memory cell array SMA2 may be disposed between the third sub word line driver block SDB3 and the fourth sub word line driver block SDB4.

Each of the plurality of sub word line driver blocks SDB1 to SDB6 includes a plurality of sub word line drivers. The sub word line drivers included in each of the plurality of sub word line driver blocks SDB1 to SDB6 are connected to word lines included in each of the first sub memory cell arrays SMA1_A to SMA1_D or the second sub memory cell array SMA2. The sub word line drivers included in the plurality of sub word line driver blocks SDB1 to SDB6 may drive corresponding word lines among the word lines included in the first sub memory cell arrays SMA1_A to SMA1_D. For example, the sub word line drivers included in the sub word line driver block SDB1 may drive some of the word lines included in the first sub word line driver block SMA1_A. The sub word line drivers included in the sub word line driver block SDB2 may drive the others of the word lines included in the first sub memory cell array SMA1_A or the first sub memory cell array SMA1_B.

The first sub memory cell arrays SMA1_A to SMA1_D may be disposed between first bit line connection areas BCA1_A, BCA1_B, . . . , BCA1_D and second bit line connection areas BCA2_A, BCA2_B, . . . , BCA2_D. For example, the first sub memory cell array SMA1_A may be disposed between the first bit line connection area BCA1_A and the second bit line connection area BCA2_A. The second sub memory cell array SMA1_B may be disposed between the first bit line connection area BCA1_B and the second bit line connection area BCA2_B. The second sub memory cell array SMA2 may be disposed between a third bit line connection area BCA3 and a fourth bit line connection area BCA4.

The first semiconductor structure SEMS1 may further include metal lines connecting the first metal pads with the bit lines disposed in the first sub memory cell arrays SMA1_A to SMA1_D and the second sub memory cell array SMA2. Metal contacts each connecting the corresponding metal line with each of the bit lines disposed in the first sub memory cell arrays SMA1_A to SMA1_D may be formed in the first bit line connection areas BCA1_A, BCA1_B, . . . , BCA1_D and the second bit line connection areas BCA2_A, BCA2_B, . . . , BCA2_D. The metal contacts each connecting the corresponding metal line with each of the bit lines disposed in the second sub memory cell array SMA2 may be formed in the third bit line connection area BCA3 and the fourth bit line connection area BCA4. For example, the metal contacts between the metal lines and the bit lines of the first sub memory cell array SMA1_A may be formed in the first bit line connection area BCA1_A and the second bit line connection area BCA2_A. The metal contacts connecting the metal lines with the bit lines disposed in the first sub memory cell array SMA1_B may be formed in the first bit line connection area BCA1_B and the second bit line connection area BCA2_B. The metal contacts connecting the metal lines with the bit lines disposed in the second sub memory cell array SMA2 may be formed in the third bit line connection area BCA3 and the fourth bit line connection area BCA4.

Each of the first sub memory cell arrays SMA1_A to SMA1_D may correspond to the memory area MA of FIG. 3. The second sub memory cell array SMA2 may correspond to the parity area PA of FIG. 3.

FIG. 13B is a plan view of an arrangement of a second semiconductor structure according to various example embodiments. Referring to FIG. 13B, the second semiconductor structure SEM2 may include a plurality of first bit line sense amplifier blocks BLSB1_A, BLSB1_B, . . . , BLSB1_D, a plurality of second bit line sense amplifier blocks BLSB2_A, BLSB2_B, . . . , BLSB2_D, a plurality of first local sense amplifier blocks LSB1_A, LSB1_B, . . . , LSB1_D, a plurality of second local sense amplifier blocks LSB2_A, LSB2_B, . . . , LSB_D, a third bit line sense amplifier block BLSB3, a fourth bit line sense amplifier block BLSB4, a plurality of first ECC engines 251_A, 251_B, . . . , 251_D, and the second ECC engine 252.

The first ECC engines 251_A, 251_B, . . . , 251_D may generate the parity data based on the write main data. The first ECC engines 251_A, 251_B, . . . , 251_D may generate the check data based on the read main data. Each of the plurality of first local sense amplifier blocks LSB1_A, LSB1_B, . . . , LSB1_D and the plurality of second local sense amplifier blocks LSB2_A, LSB2_B, . . . , LSB_D may include data correctors correcting the read main data based on the data correction signal.

Each of the first bit line sense amplifier blocks BLSB1_A to BLSB1_D and each of the second bit line sense amplifier blocks BLSB2_A to BLSB2_D may be disposed under each of the plurality of first sub memory cell arrays SMA1_A to SMA1_D. Each of the first bit line sense amplifier blocks BLSB1_A to BLSB1_D may be located under one side periphery of the lower surface of each of the plurality of first sub memory cell arrays SMA1_A to SMA1_D. Each of the second bit line sense amplifier blocks BLSB2_A to BLSB2_D may be located under an opposite side periphery of the lower surface of each of the plurality of first sub memory cell arrays SMA1_A to SMA1_D.

The first bit line sense amplifier blocks BLSB1_A to BLSB1_D and the second bit line sense amplifier blocks BLSB2_A to BLSB2_D are electrically connected to some of the second metal pads included in the second semiconductor structure SEM2. The first bit line sense amplifier blocks BLSB1_A to BLSB1_D are electrically connected to some of the bit lines of the first sub memory cell arrays SMA1_A to SMA1_D through the second metal pads, the first metal pads, and the metal lines. In the first bit line connection areas BCA1_A to BCA1_D, metal contacts connecting the metal lines and some bit lines may be formed. The second bit line sense amplifier blocks BLSB2_A to BLSB2_D are electrically connected to the others of the bit lines of the first sub memory cell arrays SMA1_A to SMA1_D through the second metal pads, the first metal pads, and the metal lines. In the second bit line connection areas BCA2_A to BCA2_D, metal contacts connecting the metal lines and the remaining bit lines may be formed.

Each of the first local sense amplifier blocks LSB1_A to LSB1_D and each of the second local sense amplifier blocks LSB2_A to LSB2_D may be disposed under each of the plurality of first sub memory cell arrays SMA1_A to SMA1_D. The first local sense amplifier blocks LSB1_A to LSB1_D may be disposed adjacent to the first bit line sense amplifier blocks BLSB1_A to BLSB1_D. The second local sense amplifier blocks LSB2_A to LSB2_D may be disposed adjacent to the second bit line sense amplifier blocks BLSB2_A to BLSB2_D.

The first ECC engines 251_A to 251_D may be respectively disposed under the plurality of first sub memory cell arrays SMA1_A to SMA1_D. The first ECC engines 251_A to 251_D may be located between the first local sense amplifier blocks LSB1_A to LSB1_D and the second local sense amplifier blocks LSB2_A to LSB2_D.

The first bit line sense amplifier block BLSB1_A, the first local sense amplifier block LSB1_A, the first ECC engine 251_A, the second local sense amplifier block LSB2_A, and the second bit line sense amplifier block BLSB2_A may vertically overlap t or at least partially vertically overlap he first sub memory cell array SMA1_A of FIG. 13A. The first bit line sense amplifier block BLSB1_B, the first local sense amplifier block LSB1_B, the first ECC engine 251_B, the second local sense amplifier block LSB2_B, and the second bit line sense amplifier block BLSB2_A may vertically overlap or at least partially vertically overlap the first sub memory cell array SMA1_B.

The third bit line sense amplifier block BLSB3 and the fourth bit line sense amplifier block BLSB4 may be disposed under the second sub memory cell array SMA2. The third bit line sense amplifier block BLSB3 may be located under one side periphery of the lower surface of the second sub memory cell array SMA2. The fourth bit line sense amplifier block BLSB4 may be located under an opposite side periphery of the lower surface of the second sub memory cell array SMA2.

The second ECC engine 252 may be disposed under the second sub memory cell array SMA2. The second ECC engine 252 may be located between the third bit line sense amplifier block BLSB3 and the fourth bit line sense amplifier block BLSB4.

The third bit line sense amplifier block BLSB3, the second ECC engine 252, and the fourth bit line sense amplifier block BLSB4 may vertically overlap the second sub memory cell array SMA2 of FIG. 13A.

The second semiconductor structure SEMS2 may further include the global sense amplifier GSA. The global sense amplifier GSA may sense and amplify outputs of the local sense amplifier blocks LSB1_A to LSB2_D so as to be transferred to the data input/output lines.

Each of the first bit line sense blocks BLSB1_A to BLSB1_D and the second bit line sense amplifier blocks BLSB2_A to BLSB2_D may correspond to the bit line sense amplifier 241 of FIG. 3.

Each of the first local sense amplifier blocks LSB1_A to LSB1_D and the second local sense amplifier blocks LSB2_A to LSB2_D may correspond to the local sense amplifier 243 of FIG. 3.

Each of the first ECC engines 251_A to 251_D may correspond to the first ECC engine 251. Each of the third bit line sense block BLSB3 and the fourth bit line sense amplifier block BLSB4 may correspond to the bit line sense amplifier 242 of FIG. 3.

The second ECC engine 252 may correspond to the second ECC engine 252 of FIG. 3.

In the write operation, the write main data may be written in the first sub memory cell arrays SMA1_A to SMA1_D. The first ECC engines 251_A to 251_D may generate the parity data based on the write main data received through the global input/output lines. Each of the first ECC engines 251_A to 251_D may provide the generated parity data to the second ECC engine 252. The parity data may be written in the second sub memory cell array SMA2.

In the read operation, the first bit line sense amplifier blocks BLSB1_A to BLSB1_D or the second bit line sense amplifier blocks BLSB2_A to BLSB2_D may sense and amplify signals corresponding to the read main data written in the first sub memory cell arrays SMA1_A to SMA1_D. The first ECC engines 251_A to 251_D may generate the check data based on the read main data received from the first sub memory cell arrays SMA1_A to SMA1_D. The first ECC engines 251_A to 251_D may provide the check data to the second ECC engine 252. The second ECC engine 252 may generate a syndrome including information about an error occurrence location based on the parity data received from the second sub memory cell array SMA2 and the check data received from the first ECC engines 251_A to 251_D. The second ECC engine 252 may generate the error correction signal based on the syndrome. The second ECC engine 252 may provide the error correction signal to the first local sense amplifier blocks LSB1_A to LSB1_D or the second local sense amplifier blocks LSB2_A to LSB2_D. Each local sense amplifier included in each of the first local sense amplifier blocks LSB1_A to LSB1_D and the second local sense amplifier blocks LSB2_A to LSB2_D may include a data corrector correcting the read main data based on the error correction signal. The first local sense amplifier blocks LSB1_A to LSB1_D or the second local sense amplifier blocks LSB2_A to LSB2_D may correct the read main data received from the first sub memory cell array SMA1_A based on the error correction signal. The first local sense amplifier blocks LSB1_A to LSB1_D or the second local sense amplifier blocks LSB2_A to LSB2_D may provide the corrected read main data to the global sense amplifier GSA.

In an embodiment, the first semiconductor structure SEMS1 of FIG. 13A may include a plurality of second sub memory cell arrays SMA2.

The sub word line driver blocks SDB1 to SDB6 included in the first semiconductor structure SEMS1 of FIG. 13A are provided as an example. In an embodiment, the sub word line driver blocks SDB1 to SDB6 may be disposed in the second semiconductor structure SEMS2. In this case, the sub word line driver blocks SDB1 to SDB6 may be electrically connected to the second metal pads of the second semiconductor structure SEMS2. The sub word line driver blocks SDB1 to SDB6 may be electrically connected to the word lines included in the first sub memory cell arrays SMA1_A to SMA1_D or the second sub memory cell array SMA2 disposed in the first semiconductor structure SEMS1 through the second metal pads, the first metal pads, and the metal lines. The sub word line driver blocks SDB1 to SDB6 included in the second semiconductor structure SEMS2 may drive the word lines disposed in the first semiconductor structure SEMS1.

The first ECC engines are located to be relatively close to the first and second bit line sense amplifier blocks BLSB1_A to BLSB2_D, and the second ECC engine 252 is located to be relatively close to the third and fourth bit line sense amplifier blocks BLSB3 and BLSB4. In this case, as a physical distance of a data path necessary to correct an error occurring in the main data becomes shorter, a signal transfer characteristic may become better. Accordingly, it may be possible to correct an error relatively quickly. Also, power consumption necessary for error correction may be reduced. As a portion of each of the first sub memory cell arrays SMA1_A to SMA1_D vertically overlaps each of the first ECC engines 251_A to 251_D and the second sub memory cell array SMA2 and the second ECC engine 252 vertically overlap each other, the area of the first semiconductor structure SEMS1 and the second semiconductor structure SEMS2, which corresponds to a plane defined by a second direction D2 and a third direction D3, may be reduced.

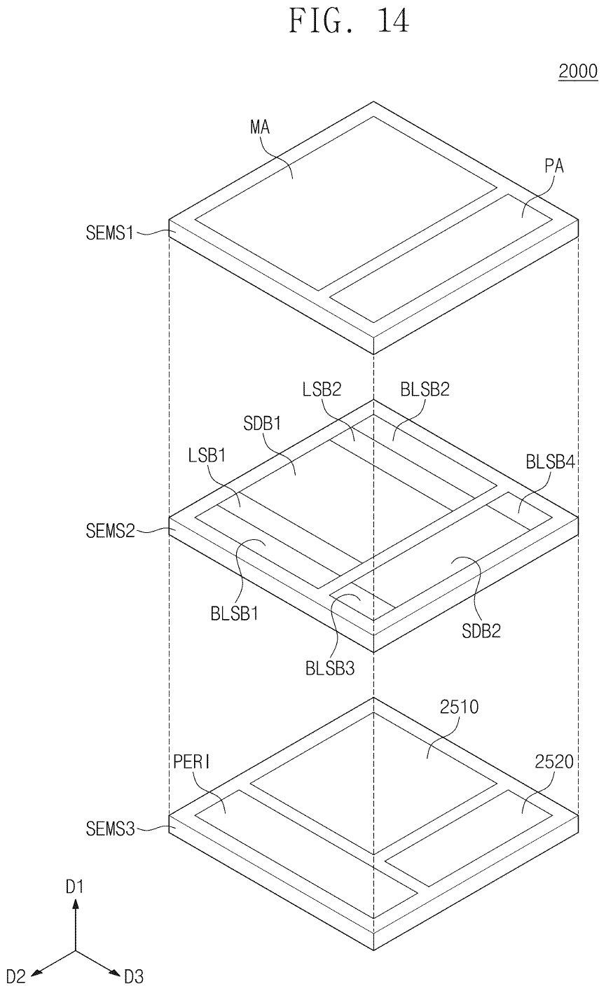

FIG. 14 is a perspective view illustrating a semiconductor memory device according to another embodiment of the present disclosure. A semiconductor memory device 2000 may include a first semiconductor structure SEMS1, a second semiconductor structure SEMS2, and a third semiconductor structure SEMS3.

The first semiconductor structure SEMS1 and the semiconductor structure SEM2 may be vertically bonded. The second semiconductor structure SEMS2 and the third semiconductor structure SEMS3 may be vertically bonded. For convenience of description, it is assumed that the second semiconductor structure SEMS2 is disposed under the first semiconductor structure SEMS1 and the third semiconductor structure SEMS3 is disposed under the second semiconductor structure SEMS2. That is, a downward direction is a direction facing away from the first direction D1.

The first semiconductor structure SEMS1 may include a memory area MA and a parity area PA. The memory area MA may include at least one sub memory cell array. The parity area PA may include at least one sub memory cell array. Bit lines and word lines are disposed in each of the sub memory cell arrays included in the first semiconductor structure SEMS1. Main data may be stored in the sub memory cell array included in the memory area MA. Parity data may be stored in the sub memory cell array included in the parity area PA.

The second semiconductor structure SEMS2 may include a first bit line sense amplifier block BLSB1, a second bit line sense amplifier block BLSB2, a first local sense amplifier block LSB1, a second local sense amplifier block LSB2, a first sub word line driver block SDB1, a third bit line sense amplifier block BLSB3, a fourth bit line sense amplifier block BLSB4, and a second sub word line driver block SDB2.

The first bit line sense amplifier block BLSB1 and the second bit line sense amplifier block BLSB2 may be disposed under memory area MA. The first bit line sense amplifier block BLSB1 may be located under one side periphery of the lower surface of the memory area MA. The second bit line sense amplifier block BLSB2 may be located under an opposite side periphery of the lower surface of the memory area MA. The first bit line sense amplifier block BLSB1 and the second bit line sense amplifier block BLSB2 are electrically connected to the bit lines disposed in the memory area MA. Bit line sense amplifiers included in the first bit line sense amplifier block BLSB1 and the second bit line sense amplifier block BLSB2 may sense and amplify signals of the plurality of bit lines disposed in the memory area MA.

The first local sense amplifier block LSB1 and the second local sense amplifier block LSB2 may be disposed under the memory area MA. The first local sense amplifier block LSB1 may be located adjacent to the first bit line sense amplifier block BLSB1. The second local sense amplifier block BLSB2 may be located adjacent to the second bit line sense amplifier block BLSB2. The first local sense amplifier block LSB1 is connected to the first bit line sense amplifier block BLSB1 through first local input/output lines, and the second local sense amplifier block LSB2 is connected to the second bit line sense amplifier block BLSB2 through second local input/output lines. The first local sense amplifier block LSB1 may sense and amplify signals output to the first local input/output lines through the first bit line sense amplifier block BLSB1. The second local sense amplifier block LSB2 may sense and amplify signals output to the second local input/output lines through the second bit line sense amplifier block BLSB2.

The first sub word line driver block SDB1 may be disposed under the memory area MA. The first sub word line driver block SDB1 may be located between the first local sense amplifier block LSB1 and the second local sense amplifier block LSB2. The first sub word line driver block SDB1 and the second sub word line driver block SDB2 are electrically connected to the word lines disposed in the memory area MA or the parity area PA. Sub word line drivers included in the first sub word line driver block SDB1 and the second sub word line driver block SDB2 are electrically connected to the word lines disposed in the memory area MA or the parity area PA based on a control signal.

The third and fourth bit line sense amplifier blocks BLSB3 and BLSB4 may be disposed under the parity area PA. The third bit line sense amplifier block BLSB3 may be located under one side periphery of the lower surface of the parity area PA. The fourth bit line sense amplifier block BLSB4 may be located under an opposite side periphery of the lower surface of the parity area PA. The third bit line sense amplifier block BLSB3 and the fourth bit line sense amplifier block BLSB4 are electrically connected to the bit lines disposed in the parity area PA. Bit line sense amplifiers included in the third bit line sense amplifier block BLSB3 and the fourth bit line sense amplifier block BLSB4 may sense and amplify signals of the bit lines disposed in the parity area PA.

The third semiconductor structure SEMS3 may include a first ECC engine 2510, a second ECC engine 2520, and a peripheral circuit PERI.

The first ECC engine 2510 may be disposed under the memory area MA. The first ECC engine 2510 is connected to the first bit line sense amplifier block BLSB1 through first local input/output lines. The first ECC engine 2510 is connected to the second bit line sense amplifier block BLSB2 through second local input/output lines. The first ECC engine 2510 may generate the check data corresponding to the write main data and may generate the check data corresponding to the read main data.

The second ECC engine 2520 may be disposed under the parity area PA. The second ECC engine 2520 is connected the third bit line sense amplifier block BLSB3 and the fourth bit line sense amplifier block BLSB4. The first ECC engine 2510 is connected to the second ECC engine 2520. The second ECC engine 2520 may generate the error correction signal based on the parity data and the check data.

The peripheral circuit PERI may be disposed in the third semiconductor structure SEMS3. The peripheral circuit PERI may include various circuits as well as the first ECC engine 2510 and the second ECC engine 2520. For example, the peripheral circuit PERI may include a global sense amplifier.

Meanwhile, the first local sense amplifier block LSB1 and the second local sense amplifier block LSB2 may include data correctors correcting the read main data based on the error correction signal.

The first bit line sense amplifier block BLSB1, the second bit line sense amplifier block BLSB2, the first local sense amplifier block LSB1, the second local sense amplifier block LSB2, and the first sub word line driver block SDB1 may vertically overlap the memory area MA. The third bit line sense amplifier block BLSB3, the fourth bit line sense amplifier block BLSB4, and the second sub word line driver block SDB2 may vertically overlap the parity area PA.

The first ECC engine 2510 may vertically overlap the memory area MA. The second ECC engine 2520 may vertically overlap the parity area PA.

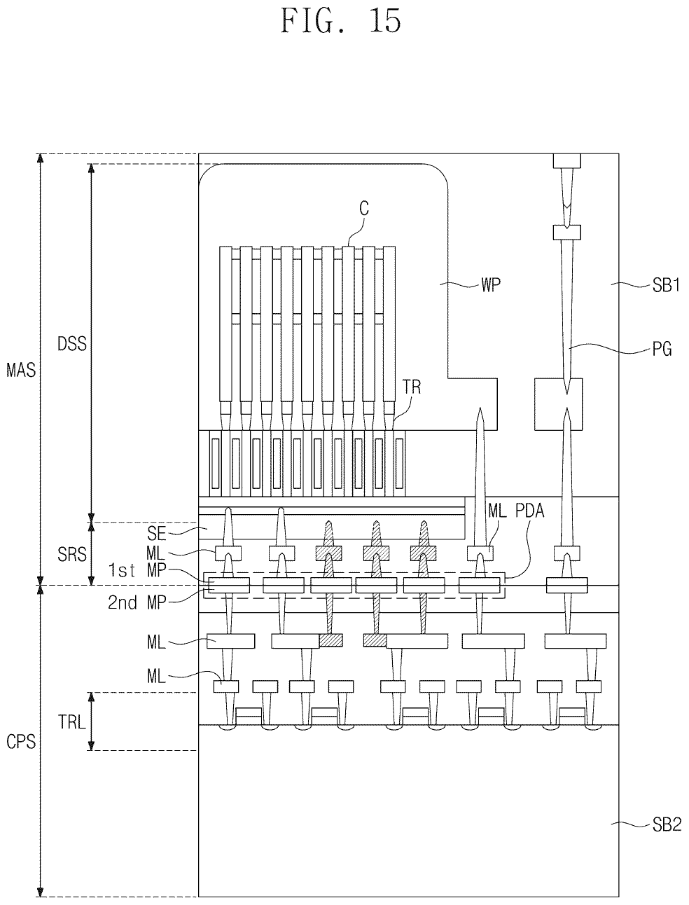

FIG. 15 is a diagram illustrating an integrated circuit device. Referring to FIG. 15, an integrated circuit device may include a memory cell array structure MAS and a core-peripheral circuit structure CPS.

The memory cell array structure MAS may be formed on a first substrate SB1. The memory cell array structure MAS may include a data storage structure DSS and a signal routing structure SRS. The data storage structure DSS may include a plurality of memory cells each including a capacitor “C” and a cell transistor TR, a plurality of bit lines, and a plurality of word lines. The signal routing structure SRS may include a plurality of first metal pads 1st MP and a plurality of metal lines ML. The plurality of metal lines ML electrically connect the plurality of first metal pads 1st MP and components of the data storage structure DSS. For example, the plurality of metal lines ML may electrically connect some of the plurality of first metal pads 1st MP and the bit lines. Also, the plurality of metal lines ML may electrically connect some of the plurality of first metal pads 1st MP and the word lines.

The core-peripheral circuit structure CPS may be formed on a second substrate SB2. The core-peripheral circuit structure CPS may include a transistor layer TRL. Various kinds of elements including a plurality of transistors for controlling or driving the bit lines and the word lines included in the data storage structure DSS may be disposed in the transistor layer TRL. Some of the plurality of elements disposed in the transistor layer TRL may be included in a bit line sense amplifier. Others of the plurality of elements disposed in the transistor layer TRL may be included in a local sense amplifier. Others of the plurality of elements disposed in the transistor layer TRL may be included in an error correction circuit.

A plurality of second metal pads 2nd MP may be disposed on the surface of the core-peripheral circuit structure CPS. Some or all of the plurality of second metal pads 2nd MP may be electrically connected to a plurality of peripheral circuits disposed in the transistor layer TRL through the plurality of metal lines ML.

The plurality of first metal pads 1st MP and the plurality of second metal pads 2nd MP are disposed in the same matrix array form and provide an electrical connection of each component included in the memory cell array structure MAS and each component included in the core-peripheral circuit structure CPS. The plurality of first metal pads 1st MP and the plurality of second metal pads 2nd MP may constitute a pad array PDA.

One or more plugs PG provide an electrical connection between the core-peripheral circuit structure CPS and the outside of the integrated circuit device. A command signal, an address signal, a data signal, or an external power is input to the core-peripheral circuit structure CPS through the one or more plugs PG.

In the integrated circuit device, because the memory cell array structure MAS and the core-peripheral circuit structure CPS are vertically disposed, the area on the plane may be reduced compared to the case where a memory cell array and peripheral circuits are disposed on one plane.

The first semiconductor structure SEMS1 of the semiconductor memory device 200 of FIG. 2 may correspond to the memory cell array structure MAS of the integrated circuit device. The second semiconductor structure SEMS2 of the semiconductor memory device 200 of FIG. 2 may correspond to the core-peripheral circuit structure CPS of the integrated circuit device.

The first semiconductor structure SEMS1 of the semiconductor memory device 2000 of FIG. 14 may correspond to the memory cell array structure MAS of the integrated circuit device. The second semiconductor structure SEMS2 and the third semiconductor structure SEMS3 of FIG. 14 may correspond to the core-peripheral circuit structure CPS of the integrated circuit device.

A number of layers of metal layers ML included in the core-peripheral circuit structure CPS is not limited to two; furthermore, a number of layers of metal layers ML included in the memory cell array structure MAS is not limited to one. Alternatively or additionally an orientation of transistors included in the core-peripheral circuit structure CPS may be the same as and/or different from the features as illustrated in FIG. 15.

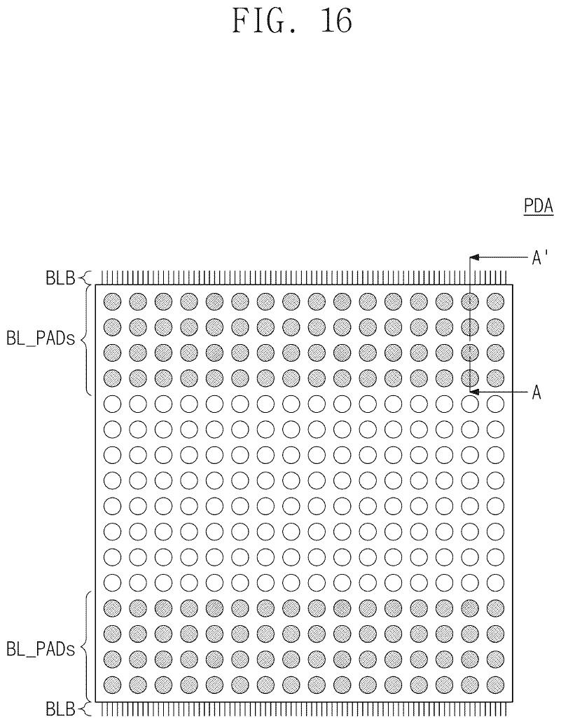

FIG. 16 is a diagram illustrating a pad array of an integrated circuit device of FIG. 15. Referring to FIG. 16, the pad array PDA may include a plurality of bit line pads BL_PADs. The pad array PDA corresponds to the plurality of first metal pads 1st MP illustrated in FIG. 11. The second metal pads 2nd MP of FIG. 11 may be disposed to be the same as the first metal pads 1st MP.

The plurality of bit line pads BL_PADs may be distributed and disposed in a first peripheral area of the plane and a second peripheral area of the plane, which faces away from the first peripheral area. The plurality of bit line pads BL_PADs may be electrically connected to a bit line connection area BLB through one or more metal layers. Signals received through the plurality of bit line pads BL_PADs disposed in a first peripheral area may be routed to a bit line connection area BLBa outside the first peripheral area, and signals received through the plurality of bit line pads BL_PADs disposed in a second peripheral area may be routed to a bit line connection area BLBb outside the second peripheral area.

The bit line connection area BLB may provide an electrical connection of the plurality of bit line pads BL_PADs and the bit lines included in the memory cell array. For example, metal contacts between the bit lines and the metal lines may be formed in the bit line connection area BLB.

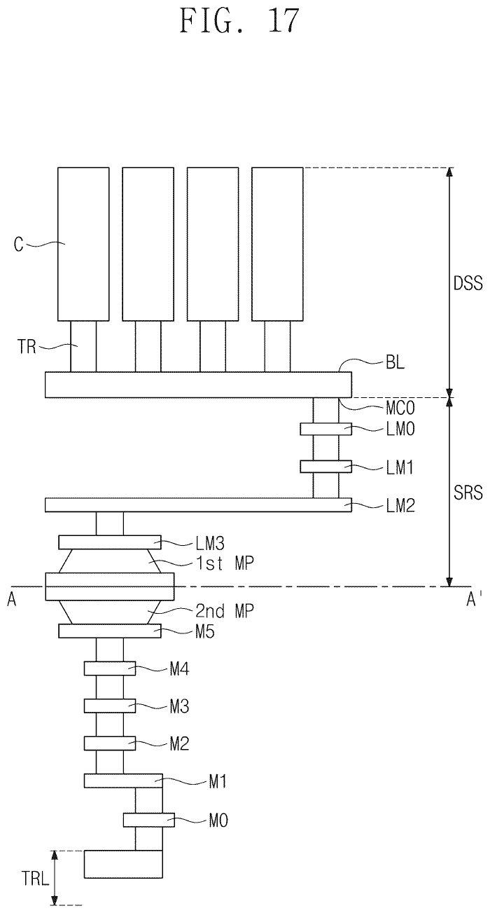

FIG. 17 is a diagram illustrating a vertical cross section of an integrated circuit device taken along line A-A′ of FIG. 16. Referring to FIG. 17, the bit line sense amplifier disposed in the transistor layer TRL may be electrically connected to the bit line BL.

The remaining components (e.g., neighboring metal pads) other than components providing the electrical connection between the bit line sense amplifier disposed in the transistor layer TRL and the bit line BL are omitted.

The data storage structure DSS may include the plurality of memristors and/or capacitors “C”, the cell transistors TR, and the plurality of bit lines BL. The signal routing structure SRS may include a plurality of metal layers LM0 to LM3 and the first metal pad 1st MP.

The bit line sense amplifier circuit disposed in the transistor layer TRL may be connected to the second metal pad 2nd MP through metal layers M0, M1, M2, M3, M4, and M5. The second metal pad 2nd MP may be bonded to the first metal pad 1st MP. That is, the second metal pad 2nd MP may be physically and electrically connected to the first metal pad 1st MP. The first metal pad 1st MP may be electrically connected to the plurality of metal lines LM3, LM2, LM1, and LM0. The metal line LM0 may be electrically connected to the bit line BL through a metal contact MCO. The metal contact MCO may be formed in the bit line connection area BLB of FIG. 16. The change in a potential of the bit line BL by the capacitor “C” and the cell transistor TR is transferred to the transistor layer TRL through the plurality of metal lines LM0 to LM3, the first metal pad 1st MP, the second metal pad 2nd MP, and the plurality of metal layers M0 to M5. The bit line sense amplifier disposed in the transistor layer TRL may amplify data stored in the capacitor “C” by amplifying the change in the potential of the bit line BL.

A semiconductor memory device according to various example embodiments includes a first semiconductor structure including a memory cell array and a second semiconductor structure disposed under the first semiconductor structure and including an error correction circuit. As the CoP structure is applied, the storage capacity of the semiconductor memory device may increase, and the degree of integration may become higher. Also, the space utilization in the semiconductor memory device may be improved. The error correction circuit may be disposed under the memory cell array. In this case, a physical distance between the memory cell array and the error correction circuit may be decreased. As the physical distance between the memory cell array and the error correction circuit is reduced, an electrical characteristic associated with signal transmission/reception between the memory cell array and the error correction circuit may be improved. This may mean that an operating speed of the semiconductor memory device is improved and power consumption is reduced.

According to various example embodiments, a semiconductor memory device with the improved degree of integration may be provided. According to various example embodiments, an electrical characteristic of a path through which data for error correction are transferred may be improved, an operating speed of the semiconductor memory device may become higher, and power consumption may be reduced.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various inventive concepts have been described with reference to example embodiments thereof, it will be apparent to those of ordinary skill in the art that various changes and modifications may be made thereto without departing from the spirit and scope of inventive concepts as set forth in the following claims. Furthermore example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a memory cell array in a first semiconductor structure and including a memory area configured to store main data and a parity area configured to store parity data corresponding to the main data;
a first ECC engine in a second semiconductor structure bonded to the first semiconductor structure through a plurality of metal pads, and configured to generate parity data corresponding to write main data and to generate check data corresponding to read main data;
a second ECC engine in the second semiconductor structure, and configured to generate an error correction signal based on the parity data and the check data; and
a data corrector in the second semiconductor structure, and configured to correct read main data read from the memory area based on the error correction signal,
wherein the first ECC engine and the data corrector at least partially vertically overlap the memory area, and the second ECC engine at least partially vertically overlaps the parity area.

2. The semiconductor memory device of claim 1, further comprising:
a first bit line sense amplifier configured to sense and amplify the main data stored in the memory area and to output the amplified main data to a local input/output line;
a local sense amplifier configured to sense and amplify a signal of the local input/output line and to output the amplified signal of the local input/output line to a global input/output line; and
a global sense amplifier configured to sense and amplify a signal of the global input/output line and to output the amplified signal of the global input/output line to a data input/output line,
wherein the first bit line sense amplifier, the local sense amplifier, and the global sense amplifier at least partially vertically overlap the memory area.

3. The semiconductor memory device of claim 2, wherein the first ECC engine is connected to the local input/output line.

4. The semiconductor memory device of claim 2, wherein the local sense amplifier includes the data corrector.

5. The semiconductor memory device of claim 2, further comprising:
a second bit line sense amplifier configured to sense and amplify the parity data stored in the parity area and to output the amplified parity data the second ECC engine,
wherein the second bit line sense amplifier at least partially vertically overlaps the parity area.

6. The semiconductor memory device of claim 1, wherein the first ECC engine includes:
a parity generator configured to generate the parity data based on the write main data; and
a check data generator configured to generate the check data based on the read main data.

7. The semiconductor memory device of claim 6, wherein the second ECC engine includes:
a syndrome generator configured to generate a syndrome based on the parity data received from the parity area and the check data received from the first ECC engine; and
a syndrome decoder configured to generate the error correction signal based on the syndrome.

8. A semiconductor memory device comprising:
a first semiconductor structure including one or more first sub memory cell arrays configured to store data and a second sub memory cell array configured to store parity data corresponding to the main data; and
a second semiconductor structure bonded to the first semiconductor structure through a plurality of bonding pads,
wherein the second semiconductor structure includes,
one or more first ECC engines configured to generate the parity data based on write main data and to generate check data based on read main data,
a second ECC engine configured to generate a data correction signal based on the parity data and the check data, and
one or more data correctors configured to correct read main data received from the first sub memory cell arrays based on the data correction signal, wherein
each of the first ECC engines and each of the data correctors at least partially vertically overlap each of the first sub memory cell arrays, and
the second ECC engine at least partially vertically overlaps the second sub memory cell array.

9. The semiconductor memory device of claim 8, wherein
the second semiconductor structure further includes one or more first bit line sense amplifier blocks and one or more second bit line sense amplifier blocks connected to bit lines of the first sub memory cell arrays,
each of the first bit line sense amplifier blocks is under one side periphery of a lower surface of each of the first sub memory cell arrays, and
each of the second bit line sense amplifier blocks is under an opposite side periphery of the lower surface of each of the first sub memory cell arrays.

10. The semiconductor memory device of claim 9, wherein the second semiconductor structure further includes:
one or more first local sense amplifier blocks adjacent to the first bit line sense amplifier blocks; and
one or more second local sense amplifier blocks adjacent to the second bit line sense amplifier blocks.

11. The semiconductor memory device of claim 10, wherein each of the first local sense amplifier blocks and the second local sense amplifier blocks includes the data correctors.

12. The semiconductor memory device of claim 10, wherein the first ECC engines are respectively between the first local sense amplifier blocks and the second local sense amplifier blocks.

13. The semiconductor memory device of claim 8, wherein the second semiconductor structure further includes:
a third bit line sense amplifier block and a fourth bit line sense amplifier block connected to bit lines of the second sub memory cell array,
wherein the third bit line sense amplifier block is under one side periphery of a lower surface of the second sub memory cell array, and
the fourth bit line sense amplifier block is under an opposite side periphery of the lower surface of the second sub memory cell array.

14. The semiconductor memory device of claim 13, wherein the second ECC engine is between the third bit line sense amplifier block and the fourth bit line sense amplifier block.

15. The semiconductor memory device of claim 8, wherein the first semiconductor structure further includes:
one or more sub word line driver blocks configured to drive word lines in at least one of the first sub memory cell arrays or the second sub memory cell array.

16. The semiconductor memory device of claim 15, wherein the sub word line driver blocks and the first and second sub memory cell arrays are alternately arranged.

17. A semiconductor memory device comprising:
a first semiconductor structure including a memory area configured to store main data and a parity area configured to store parity data corresponding to the main data;
a second semiconductor structure including a first bit line sense amplifier block and a second bit line sense amplifier block connected to bit lines of the memory area, a first local sense amplifier block connected to the first bit line sense amplifier block, a second local sense amplifier block connected to the second bit line sense amplifier block, a third bit line sense amplifier block and a fourth bit line sense amplifier block connected to bit lines of the parity area, and a first sub word line driver block and a second sub word line driver block configured to drive word lines of at least one of the memory area or the parity area; and
a third semiconductor structure including an error correction circuit configured to generate the parity data based on write main data and to generate an error correction signal based on the parity data,
wherein each of the first local sense amplifier block and the second local sense amplifier block includes data correctors configured to correct read main data based on the error correction signal.

18. The semiconductor memory device of claim 17, wherein the error correction circuit includes:
a first error correction circuit (ECC) engine configured to generate the parity data corresponding to the write main data and to generate check data corresponding to read main data; and
a second ECC engine configured to generate the error correction signal based on the parity data and the check data,
wherein the first ECC engine and the data correctors at least partially vertically overlap the memory area, and the second ECC engine at least partially vertically overlaps the parity area.

19. The semiconductor memory device of claim 18, wherein
the first bit line sense amplifier block is under one side periphery of a lower surface of the memory area,
the second bit line sense amplifier block is under an opposite side periphery of the lower surface of the memory area,
the first local sense amplifier block is adjacent to the first bit line sense amplifier block,
the second local sense amplifier block is adjacent to the second bit line sense amplifier block, and
the first ECC engine is between the first local sense amplifier block and the second local sense amplifier block.

20. The semiconductor memory device of claim 17, wherein
the third bit line sense amplifier block is under one side periphery of a lower surface of the parity area,
the fourth bit line sense amplifier block is under an opposite side periphery of the lower surface of the parity area, and
the second sub word line driver block is between the third bit line sense amplifier block and the fourth bit line sense amplifier block.
